(19) United States
(12) Patent Application Publication
(10) Pub. No.: US 2022/0301510 A1
(43) Pub. Date: Sep. 22, 2022

(54) SHIFT REGISTER AND CONTROL METHOD THEREFOR, GATE DRIVING CIRCUIT, AND DISPLAY PANEL

(71) Applicants: HEFEI XINSHENG OPTOELECTRONICS TECHNOLOGY CO., LTD., Anhui (CN); BOE TECHNOLOGY GROUP CO., LTD., Beijing (CN)

(72) Inventors: Rui MA, Beijing (CN); Tong YANG, Beijing (CN); Suzhen MU, Beijing (CN); Xianjie SHAO, Beijing (CN)

(73) Assignees: HEFEI XINSHENG OPTOELECTRONICS TECHNOLOGY CO., LTD., Anhui (CN); BOE TECHNOLOGY GROUP CO., LTD., Beijing (CN)

(21) Appl. No.: 17/641,547

(22) PCT Filed: Jan. 7, 2021
(86) PCT No.: PCT/CN2021/070583

§ 371 Date: Mar. 9, 2022

(30) Foreign Application Priority Data
Jan. 8, 2020 (CN) 202010019234.6

(51) Int. Cl. G09G 3/36; G11C 19/28

(52) U.S. Cl. CPC G09G 3/3677; G11C 19/28; G09G 2310/0286; G09G 2300/0426; G09G 2310/061

(57) ABSTRACT

A shift register includes: an input circuit configured to, under control of an input signal transmitted by an input signal terminal, transmit the input signal to a pull-up node; a first control circuit configured to, under control of a first voltage signal transmitted by a first voltage signal terminal, transmit the first voltage signal to a first pull-down node, and under control of a voltage of the pull-up node, transmit a second voltage signal received at a second voltage signal terminal to the first pull-down node; and an output circuit configured to transmit a clock signal received at a clock signal terminal to a first output signal terminal under the control of the voltage of the pull-up node. The first control circuit is further configured to, receive the input signal, and transmit the second voltage signal to the first pull-down node under the control of the input signal.

### CROSS-REFERENCE TO RELATED APPLICATIONS

This application is a national phase entry under 35 USC 371 of International Patent Application No. PCT/CN2021/070583, filed on Jan. 7, 2021, which claims priority to Chinese Patent Application No. 202010019234.6, filed on Jan. 8, 2020, which are incorporated herein by reference in their entirety.

### TECHNICAL FIELD

The present disclosure relates to the field of display technologies, and in particular, to shift registers and a control method for a shift register, a gate driving circuit, and a display panel.

### BACKGROUND

During display of a display apparatus (or a display panel), a gate driving circuit needs to be used to scan all sub-pixels. The gate driving circuit generally includes a plurality of shift registers connected in cascade. Each shift register, for example, is electrically connected to a row of sub-pixels, and transmits a scanning signal to the row of sub-pixels, so that each row of sub-pixels may be scanned row by row, and the display apparatus (or the display panel) may display an image.

### SUMMARY

In an aspect, a shift register is provided. The shift register includes an input circuit, a first control circuit and an output circuit. The input circuit is electrically connected to an input signal terminal and a pull-up node. The input circuit is configured to, under control of an input signal transmitted by the input signal terminal, transmit the input signal to the pull-up node. The first control circuit is electrically connected to a first voltage signal terminal, the pull-up node, a first pull-down node and a second voltage signal terminal. The first control circuit is configured to: under control of a first voltage signal transmitted by the first voltage signal terminal, transmit the first voltage signal to the first pull-down node; and under control of a voltage of the pull-up node, transmit a second voltage signal received at the second voltage signal terminal to the first pull-down node. The output circuit is electrically connected to the pull-up node, a clock signal terminal and a first output signal terminal. The output circuit is configured to transmit a clock signal received at the clock signal terminal to the first output signal terminal under the control of the voltage of the pull-up node. The first control circuit is further electrically connected to the input signal terminal. The first control circuit is further configured to, in a period when the input circuit transmits the input signal to the pull-up node, receive the input signal, and transmit the second voltage signal to the first pull-down node under the control of the input signal.

In some embodiments, the first control circuit includes a second transistor, a third transistor and a fourth transistor. A gate of the second transistor is electrically connected to the first voltage signal terminal, a first electrode of the second transistor is electrically connected to the first voltage signal terminal, and a second electrode of the second transistor is electrically connected to the first pull-down node. A gate of the third transistor is electrically connected to the pull-up node, a first electrode of the third transistor is electrically connected to the second voltage signal terminal, and a second electrode of the third transistor is electrically connected to the first pull-down node. A gate of the fourth transistor is electrically connected to the input signal terminal, a first electrode of the fourth transistor is electrically connected to the second voltage signal terminal, and a second electrode of the fourth transistor is electrically connected to the first pull-down node.

In some embodiments, the first control circuit further includes a sixth transistor. A gate of the sixth transistor is electrically connected to the first voltage signal terminal, a first electrode of the sixth transistor is electrically connected to the first voltage signal terminal, and a second electrode of the sixth transistor is electrically connected to the gate of the second transistor.

In some embodiments, the first control circuit further includes a seventh transistor. A gate of the seventh transistor is electrically connected to the pull-up node, a first electrode of the seventh transistor is electrically connected to the second voltage signal terminal, and a second electrode of the seventh transistor is electrically connected to the second electrode of the sixth transistor.

In some embodiments, the input circuit includes a first transistor. A gate of the first transistor is electrically connected to the input signal terminal, a first electrode of the first transistor is electrically connected to the input signal terminal, and a second electrode of the first transistor is electrically connected to the pull-up node. The output circuit includes a fifth transistor and a capacitor. A gate of the fifth transistor is electrically connected to the pull-up node, a first electrode of the fifth transistor is electrically connected to the clock signal terminal, and a second electrode of the fifth transistor is electrically connected to the first output signal terminal. A first terminal of the capacitor is electrically connected to the pull-up node, and a second terminal of the capacitor is electrically connected to the first output signal terminal.

In some embodiments, the shift register further includes a first noise reduction circuit and/or a second noise reduction circuit. The first noise reduction circuit is electrically connected to the first pull-down node, the first output signal terminal and a third voltage signal terminal. The first noise reduction circuit is configured to transmit a third voltage signal received at the third voltage signal terminal to the first output signal terminal under control of a voltage of the first pull-down node, so as to reduce noise of the first output signal terminal. The second noise reduction circuit is electrically connected to the pull-up node, the second voltage signal terminal and the first pull-down node. The second noise reduction circuit is configured to transmit the second voltage signal received at the second voltage signal terminal to the pull-up node under the control of the voltage of the first pull-down node, so as to reduce noise of the pull-up node.

In some embodiments, the first noise reduction circuit includes an eighth transistor. A gate of the eighth transistor is electrically connected to the first pull-down node, a first electrode of the eighth transistor is electrically connected to the third voltage signal terminal, and a second electrode of the eighth transistor is electrically connected to the first output signal terminal. The second noise reduction circuit includes a ninth transistor. A gate of the ninth transistor is electrically connected to the first pull-down node, a first electrode of the ninth transistor is electrically connected to the second voltage signal terminal, and a second electrode of the ninth transistor is electrically connected to the pull-up node.

In some embodiments, the shift register further includes a first reset circuit and/or a second reset circuit. The first reset circuit is electrically connected to the pull-up node, a first reset signal terminal and the second voltage signal terminal. The first reset circuit is configured to transmit the second voltage signal received at the second voltage signal terminal to the pull-up node under control of a first reset signal transmitted by the first reset signal terminal, so as to reset the pull-up node. The second reset circuit is electrically connected to a second reset signal terminal, the pull-up node and the second voltage signal terminal. The second reset circuit is configured to transmit the second voltage signal received at the second voltage signal terminal to the pull-up node under control of a second reset signal transmitted by the second reset signal terminal, so as to reset the pull-up node.

In some embodiments, the first reset circuit includes a tenth transistor. A gate of the tenth transistor is electrically connected to the first reset signal terminal, a first electrode of the tenth transistor is electrically connected to the second voltage signal terminal, and a second electrode of the tenth transistor is electrically connected to the pull-up node. The second reset circuit includes an eleventh transistor. A gate of the eleventh transistor is electrically connected to the second reset signal terminal, a first electrode of the eleventh transistor is electrically connected to the second voltage signal terminal, and a second electrode of the eleventh transistor is electrically connected to the pull-up node.

In some embodiments, the shift register further includes a cascade circuit. The cascade circuit is electrically connected to the pull-up node, the clock signal terminal and a second output signal terminal. The cascade circuit is configured to transmit the clock signal received at the clock signal terminal to the second output signal terminal under the control of the voltage of the pull-up node.

In some embodiments, the cascade circuit includes a twelfth transistor. A gate of the twelfth transistor is electrically connected to the pull-up node, a first electrode of the twelfth transistor is electrically connected to the clock signal terminal, and a second electrode of the twelfth transistor is electrically connected to the second output signal terminal.

In some embodiments, the shift register further includes a third noise reduction circuit. The third noise reduction circuit is electrically connected to the first pull-down node, the second output signal terminal and the second voltage signal terminal. The third noise reduction circuit is configured to transmit the second voltage signal received at the second voltage signal terminal to the second output signal terminal under control of a voltage of the first pull-down node, so as to reduce noise of the second output signal terminal.

In some embodiments, the third noise reduction circuit includes a thirteenth transistor. A gate of the thirteenth transistor is electrically connected to the first pull-down node, a first electrode of the thirteenth transistor is electrically connected to the second voltage signal terminal, and a second electrode of the thirteenth transistor is electrically connected to the second output signal terminal.

In some embodiments, the shift register further includes a second control circuit. The second control circuit is electrically connected to a fourth voltage signal terminal, the pull-up node, a second pull-down node and the second voltage signal terminal. The second control circuit is configured to: under control of a fourth voltage signal transmitted by the fourth voltage signal terminal, transmit the fourth voltage signal to the second pull-down node; and under the control of the voltage of the pull-up node, transmit the second voltage signal received at the second voltage signal terminal to the second pull-down node. The second control circuit is further electrically connected to the input signal terminal. The second control circuit is further configured to, in the period when the input circuit transmits the input signal to the pull-up node, receive the input signal, and transmit the second voltage signal to the second pull-down node under the control of the input signal. In a case where the shift register further includes the first noise reduction circuit, the first noise reduction circuit is further electrically connected to the second pull-down node. The first noise reduction circuit is further configured to transmit the third voltage signal received at the third voltage signal terminal to the first output signal terminal under control of a voltage of the second pull-down node, so as to reduce noise of the first output signal terminal. In a case where the shift register further includes the second noise reduction circuit, the second noise reduction circuit is further electrically connected to the second pull-down node. The second noise reduction circuit is further configured to transmit the second voltage signal received at the second voltage signal terminal to the pull-up node under the control of the voltage of the second pull-down node, so as to reduce noise of the pull-up node. In a case where the shift register further includes the third noise reduction circuit, the third noise reduction circuit is further electrically connected to the second pull-down node. The third noise reduction circuit is further configured to transmit the second voltage signal received at the second voltage signal terminal to the second output signal terminal under the control of the voltage of the second pull-down node, so as to reduce noise of the second output signal terminal.

In some embodiments, the second control circuit includes a fourteenth transistor, a fifteenth transistor and a sixteenth transistor. A gate of the fourteenth transistor is electrically connected to the fourth voltage signal terminal, a first electrode of the fourteenth transistor is electrically connected to the fourth voltage signal terminal, and a second electrode of the fourteenth transistor is electrically connected to the second pull-down node. A gate of the fifteenth transistor is electrically connected to the pull-up node, a first electrode of the fifteenth transistor is electrically connected to the second voltage signal terminal, and a second electrode of the fifteenth transistor is electrically connected to the second pull-down node. A gate of the sixteenth transistor is electrically connected to the input signal terminal, a first electrode of the sixteenth transistor is electrically connected to the second voltage signal terminal, and a second electrode of the sixteenth transistor is electrically connected to the second pull-down node. The first noise reduction circuit further includes a seventeenth transistor. A gate of the seventeenth transistor is electrically connected to the second pull-down node, a first electrode of the seventeenth transistor is electrically connected to the third voltage signal terminal, and a second electrode of the seventeenth transistor is electrically connected to the first output signal terminal. The second noise reduction circuit further includes an eighteenth transistor. A gate of the eighteenth transistor is electrically connected to the second pull-down node, a first electrode of the eighteenth transistor is electrically connected to the second voltage signal terminal, and a second electrode of the eighteenth transistor is electrically connected to the pull-up node. The third noise reduction circuit further includes a nineteenth transistor. A gate of the nineteenth transistor is electrically connected to the second pull-down node, a first electrode of the nineteenth transistor is electrically connected to the second voltage signal terminal, and a second electrode of the nineteenth transistor is electrically connected to the second output signal terminal.

In some embodiments, the second control circuit further includes a twentieth transistor. A gate of the twentieth transistor is electrically connected to the fourth voltage signal terminal, a first electrode of the twentieth transistor is electrically connected to the fourth voltage signal terminal, and a second electrode of the twentieth transistor is electrically connected to the gate of the fourteenth transistor.

In some embodiments, the second control circuit further includes a twenty-first transistor. A gate of the twenty-first transistor is electrically connected to the pull-up node, a first electrode of the twenty-first transistor is electrically connected to the second voltage signal terminal, and a second electrode of the twenty-first transistor is electrically connected to the second electrode of the twentieth transistor.

In another aspect, a shift register is provided. The shift register includes an input circuit, a first control circuit, a second control circuit, an output circuit, a first noise reduction circuit, a second noise reduction circuit, a first reset circuit, a second reset circuit, a cascade circuit and a third noise reduction circuit. The input circuit is electrically connected to an input signal terminal and a pull-up node. The input circuit is configured to, under control of an input signal transmitted by the input signal terminal, transmit the input signal to the pull-up node. The first control circuit is electrically connected to a first voltage signal terminal, the pull-up node, a first pull-down node and a second voltage signal terminal; the first control circuit is configured to: under control of a first voltage signal transmitted by the first voltage signal terminal, transmit the first voltage signal to the first pull-down node; and under control of a voltage of the pull-up node, transmit a second voltage signal received at the second voltage signal terminal to the first pull-down node. The second control circuit is electrically connected to a fourth voltage signal terminal, the pull-up node, a second pull-down node and the second voltage signal terminal. The second control circuit is configured to: under control of a fourth voltage signal transmitted by the fourth voltage signal terminal, transmit the fourth voltage signal to the second pull-down node; and under the control of the voltage of the pull-up node, transmit the second voltage signal received at the second voltage signal terminal to the second pull-down node. The output circuit is electrically connected to the pull-up node, a clock signal terminal and a first output signal terminal. The output circuit is configured to transmit a clock signal received at the clock signal terminal to the first output signal terminal under the control of the voltage of the pull-up node. The first noise reduction circuit is electrically connected to the first pull-down node, the second pull-down node, the first output signal terminal and a third voltage signal terminal. The first noise reduction circuit is configured to: transmit a third voltage signal received at the third voltage signal terminal to the first output signal terminal under control of a voltage of the first pull-down node, so as to reduce noise of the first output signal terminal; and transmit the third voltage signal received at the third voltage signal terminal to the first output signal terminal under control of a voltage of the second pull-down node, so as to reduce the noise of the first output signal terminal. The second noise reduction circuit is electrically connected to the pull-up node, the second pull-down node, the second voltage signal terminal and the first pull-down node. The second noise reduction circuit is configured to: transmit the second voltage signal received at the second voltage signal terminal to the pull-up node under the control of the voltage of the first pull-down node, so as to reduce noise of the pull-up node; and transmit the second voltage signal received at the second voltage signal terminal to the pull-up node under the control of the voltage of the second pull-down node, so as to reduce the noise of the pull-up node. The first reset circuit is electrically connected to the pull-up node, a first reset signal terminal and the second voltage signal terminal. The first reset circuit is configured to transmit the second voltage signal received at the second voltage signal terminal to the pull-up node under control of a first reset signal transmitted by the first reset signal terminal, so as to reset the pull-up node. The second reset circuit is electrically connected to a second reset signal terminal, the pull-up node and the second voltage signal terminal. The second reset circuit is configured to transmit the second voltage signal received at the second voltage signal terminal to the pull-up node under control of a second reset signal transmitted by the second reset signal terminal, so as to reset the pull-up node. The cascade circuit is electrically connected to the pull-up node, the clock signal terminal and a second output signal terminal. The cascade circuit is configured to transmit the clock signal received at the clock signal terminal to the second output signal terminal under the control of the voltage of the pull-up node. The third noise reduction circuit is electrically connected to the first pull-down node, the second pull-down node, the second output signal terminal and the second voltage signal terminal. The third noise reduction circuit is configured to: transmit the second voltage signal received at the second voltage signal terminal to the second output signal terminal under the control of the voltage of the first pull-down node, so as to reduce noise of the second output signal terminal; and transmit the second voltage signal received at the second voltage signal terminal to the second output signal terminal under the control of the voltage of the second pull-down node, so as to reduce the noise of the second output signal terminal. The first control circuit is further electrically connected to the input signal terminal. The first control circuit is further configured to, in a period when the input circuit transmits the input signal to the pull-up node, receive the input signal, and transmit the second voltage signal to the first pull-down node under the control of the input signal. The second control circuit is further electrically connected to the input signal terminal. The second control circuit is further configured to, in the period when the input circuit transmits the input signal to the pull-up node, receive the input signal, and transmit the second voltage signal to the second pull-down node under the control of the input signal.

In some embodiments, the input circuit includes a first transistor. A gate of the first transistor is electrically connected to the input signal terminal, a first electrode of the first transistor is electrically connected to the input signal terminal, and a second electrode of the first transistor is electrically connected to the pull-up node. The first control circuit includes a second transistor, a third transistor and a fourth transistor. A gate of the second transistor is electrically connected to the first voltage signal terminal, a first electrode of the second transistor is electrically connected to the first voltage signal terminal, and a second electrode of the second transistor is electrically connected to the first pull-down node. A gate of the third transistor is electrically connected to the pull-up node, a first electrode of the third transistor is electrically connected to the second voltage signal terminal, and a second electrode of the third transistor is electrically connected to the first pull-down node. A gate of the fourth transistor is electrically connected to the input signal terminal, a first electrode of the fourth transistor is electrically connected to the second voltage signal terminal, and a second electrode of the fourth transistor is electrically connected to the first pull-down node. The second control circuit includes a fourteenth transistor, a fifteenth transistor and a sixteenth transistor. A gate of the fourteenth transistor is electrically connected to the fourth voltage signal terminal, a first electrode of the fourteenth transistor is electrically connected to the fourth voltage signal terminal, and a second electrode of the fourteenth transistor is electrically connected to the second pull-down node. A gate of the fifteenth transistor is electrically connected to the pull-up node, a first electrode of the fifteenth transistor is electrically connected to the second voltage signal terminal, and a second electrode of the fifteenth transistor is electrically connected to the second pull-down node. A gate of the sixteenth transistor is electrically connected to the input signal terminal, a first electrode of the sixteenth transistor is electrically connected to the second voltage signal terminal, and a second electrode of the sixteenth transistor is electrically connected to the second pull-down node. The output circuit includes a fifth transistor and a capacitor. A gate of the fifth transistor is electrically connected to the pull-up node, a first electrode of the fifth transistor is electrically connected to the clock signal terminal, and a second electrode of the fifth transistor is electrically connected to the first output signal terminal. A first terminal of the capacitor is electrically connected to the pull-up node, and a second terminal of the capacitor is electrically connected to the first output signal terminal. The first noise reduction circuit includes an eighth transistor and a seventeenth transistor. A gate of the eighth transistor is electrically connected to the first pull-down node, a first electrode of the eighth transistor is electrically connected to the third voltage signal terminal, and a second electrode of the eighth transistor is electrically connected to the first output signal terminal. A gate of the seventeenth transistor is electrically connected to the second pull-down node, a first electrode of the seventeenth transistor is electrically connected to the third voltage signal terminal, and a second electrode of the seventeenth transistor is electrically connected to the first output signal terminal. The second noise reduction circuit includes a ninth transistor and an eighteenth transistor. A gate of the ninth transistor is electrically connected to the first pull-down node, a first electrode of the ninth transistor is electrically connected to the second voltage signal terminal, and a second electrode of the ninth transistor is electrically connected to the pull-up node. A gate of the eighteenth transistor is electrically connected to the second pull-down node, a first electrode of the eighteenth transistor is electrically connected to the second voltage signal terminal, and a second electrode of the eighteenth transistor is electrically connected to the pull-up node. The first reset circuit includes a tenth transistor. A gate of the tenth transistor is electrically connected to the first reset signal terminal, a first electrode of the tenth transistor is electrically connected to the second voltage signal terminal, and a second electrode of the tenth transistor is electrically connected to the pull-up node. The second reset circuit includes an eleventh transistor. A gate of the eleventh transistor is electrically connected to the second reset signal terminal, a first electrode of the eleventh transistor is electrically connected to the second voltage signal terminal, and a second electrode of the eleventh transistor is electrically connected to the pull-up node. The cascade circuit includes a twelfth transistor. A gate of the twelfth transistor is electrically connected to the pull-up node, a first electrode of the twelfth transistor is electrically connected to the clock signal terminal, and a second electrode of the twelfth transistor is electrically connected to the second output signal terminal. The third noise reduction circuit includes a thirteenth transistor and a nineteenth transistor. A gate of the thirteenth transistor is electrically connected to the first pull-down node, a first electrode of the thirteenth transistor is electrically connected to the second voltage signal terminal, and a second electrode of the thirteenth transistor is connected to the second output signal terminal. A gate of the nineteenth transistor is electrically connected to the second pull-down node, a first electrode of the nineteenth transistor is electrically connected to the second voltage signal terminal, and a second electrode of the nineteenth transistor is electrically connected to the second output signal terminal.

In yet another aspect, a gate driving circuit is provided. The gate driving circuit includes a plurality of shift registers connected in cascade according to any one of the above embodiments. In the plurality of shift registers connected in cascade in the gate driving circuit, an input signal terminal of a first shift register is electrically connected to a start signal terminal, and except the first shift register, an input signal terminal of each shift register is electrically connected to a first output signal terminal of a previous shift register; or in a case where the shift register includes the cascade circuit, in the plurality of shift registers connected in cascade in the gate driving circuit, an input signal terminal of a first shift register is electrically connected to a start signal terminal, and except the first shift register, an input signal terminal of each shift register is electrically connected to a second output signal terminal of a previous shift register.

In yet another aspect, a display panel is provided. The display panel includes the gate driving circuit according to any one of the above embodiments.

In yet another aspect, a control method for the shift register according to any one of the above embodiments is provided. The control method includes: in an input period, in response to the input signal received at the input signal terminal, the input circuit being turned on, and transmitting the input signal to the pull-up node; in response to the input signal received at the input signal terminal, the first control circuit being turned on, and transmitting the second voltage signal received at the second voltage signal terminal to the first pull-down node; transmitting, by the first control circuit, the second voltage signal to the first pull-down node under the control of the voltage of the pull-up node; and under the control of the voltage of the pull-up node, the output circuit being turned on, and transmitting the clock signal received at the clock signal terminal to the first output signal terminal.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, and are not limitations on actual sizes of products, an actual process of a method and actual timings of signals involved in the embodiments of the present disclosure.

FIG. 1 is a diagram showing a structure of a display panel, in accordance with some embodiments of the present disclosure;

FIG. 2 is a diagram showing a structure of a sub-pixel, in accordance with some embodiments of the present disclosure;

FIG. 3 is a circuit diagram of a shift register, in accordance with some embodiments of the present disclosure;

FIG. 4 is a circuit diagram of another shift register, in accordance with some embodiments of the present disclosure;

FIG. 5 is a circuit diagram of yet another shift register, in accordance with some embodiments of the present disclosure;

FIG. 6 is a diagram showing a structure of a shift register, in accordance with some embodiments of the present disclosure;

FIG. 7 is a circuit diagram of yet another shift register, in accordance with some embodiments of the present disclosure;

FIG. 8 is a diagram showing a structure of another shift register, in accordance with some embodiments of the present disclosure;

FIG. 9 is a circuit diagram of yet another shift register, in accordance with some embodiments of the present disclosure;

FIG. 10 is a diagram showing a structure of yet another shift register, in accordance with some embodiments of the present disclosure;

FIG. 11 is a circuit diagram of yet another shift register, in accordance with some embodiments of the present disclosure;

FIG. 12 is a diagram showing a structure of yet another shift register, in accordance with some embodiments of the present disclosure;

FIG. 13 is a circuit diagram of yet another shift register, in accordance with some embodiments of the present disclosure;

FIG. 14 is a diagram showing a structure of yet another shift register, in accordance with some embodiments of the present disclosure;

FIG. 15 is a circuit diagram of yet another shift register, in accordance with some embodiments of the present disclosure;

FIG. 16 is a diagram showing a structure of yet another shift register, in accordance with some embodiments of the present disclosure;

FIG. 17 is a circuit diagram of yet another shift register, in accordance with some embodiments of the present disclosure;

FIG. 18 is a diagram showing a structure of yet another shift register, in accordance with some embodiments of the present disclosure;

FIG. 19 is a circuit diagram of yet another shift register, in accordance with some embodiments of the present disclosure;

FIG. 20 is a diagram showing a structure of yet another shift register, in accordance with some embodiments of the present disclosure;

FIG. 21 is a circuit diagram of yet another shift register, in accordance with some embodiments of the present disclosure;

FIG. 22 is a diagram showing a structure of yet another shift register, in accordance with some embodiments of the present disclosure;

FIG. 23 is a circuit diagram of yet another shift register, in accordance with some embodiments of the present disclosure;

FIG. 24 is a diagram showing a structure of yet another shift register, in accordance with some embodiments of the present disclosure;

FIG. 25 is a circuit diagram of yet another shift register, in accordance with some embodiments of the present disclosure;

FIG. 26 is a diagram showing a structure of yet another shift register, in accordance with some embodiments of the present disclosure;

FIG. 27 is a circuit diagram of yet another shift register, in accordance with some embodiments of the present disclosure;

FIG. 28 is a circuit diagram of a shift register, in accordance with an implementation;

FIG. 29 is a diagram showing a structure of a gate driving circuit, in accordance with some embodiments of the present disclosure;

FIG. 30 is a diagram showing a structure of another gate driving circuit, in accordance with some embodiments of the present disclosure;

FIG. 31 is a diagram showing a structure of yet another gate driving circuit, in accordance with some embodiments of the present disclosure; and

FIG. 32 is a diagram showing an operation timing of a shift register, in accordance with some embodiments of the present disclosure.

### DETAILED DESCRIPTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive meaning, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments or examples in any suitable manner.

Hereinafter, the terms “first” and “second” are only used for descriptive purposes, and are not to be construed as indicating or implying relative importance or implicitly indicating the number of indicated technical features. Thus, a feature defined with “first” or “second” may explicitly or implicitly include one or more of the features. In the description of the embodiments of the present disclosure, the term “a plurality of/the plurality of” means two or more unless otherwise specified.

In the description of some embodiments, the term “connected” and its derivatives may be used. For example, the term “connected” may be used in the description of some embodiments to indicate that two or more components are in direct physical or electrical contact with each other. The embodiments disclosed herein are not necessarily limited to the contents herein.

In the description of some embodiments, the sentence that “A and B are electrically connected” may mean that A and B are directly electrically connected, or C is provided between A and B, and A and B are indirectly electrically connected through C.

The phrase “A and/or B” includes the following three combinations: only A, only B, and a combination of A and B.

As used herein, the term “if”, depending on the context, is optionally construed as “when”, “in a case where”, “in response to determining”, or “in response to detecting”. Similarly, depending on the context, the phrase “if it is determined” or “if [a stated condition or event] is detected” is optionally construed as “in a case where it is determined”, “in response to determining”, “in a case where [the stated condition or event] is detected”, or “in response to detecting [the stated condition or event]”.

The use of the phrase “applicable to” or “configured to” herein is meant as an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

The term such as “about”, “substantially” or “approximately” as used herein includes a stated value and an average value within an acceptable range of deviation of a particular value. The acceptable range of deviation is determined by a person of ordinary skill in the art in view of measurement in question and errors associated with measurement of a particular quantity (i.e., limitations of a measurement system).

Exemplary embodiments are described herein with reference to sectional views and/or plan views as idealized exemplary drawings. In the accompanying drawings, thickness of layers and sizes of regions are enlarged for clarity. Therefore, variations in shapes with respect to the accompanying drawings due to, for example, manufacturing technologies and/or tolerances may be envisaged. Therefore, the exemplary embodiments should not be construed as being limited to the shapes of the regions shown herein, but including deviations in the shapes due to, for example, manufacturing. For example, an etched region shown in a rectangular shape generally has a curved feature. Therefore, the regions shown in the accompanying drawings are schematic in nature, and their shapes are not intended to show actual shapes of the region in a device, and are not intended to limit the scope of the exemplary embodiments.

Transistors used in circuits provided in the embodiments of the present disclosure may be thin film transistors, field effect transistors, or other switching devices with same characteristics. The embodiments of the present disclosure are described by taking an example in which the transistors are thin film transistors.

In some embodiments, a control electrode of each transistor used in a shift register is a gate of the transistor, a first electrode of the transistor is one of a source and a drain of the transistor, and a second electrode of the transistor is the other of the source and the drain of the transistor. Since the source and the drain of the transistor may be symmetrical in structure, there may be no difference in structure between the source and the drain of the transistor. That is, the first electrode and the second electrode of the transistor in the embodiments of the present disclosure may be the same in structure. For example, in a case where the transistor is a P-type transistor, the first electrode of the transistor is the source, and the second electrode of the transistor is the drain. For example, in a case where the transistor is an N-type transistor, the first electrode of the transistor is the drain, and the second electrode of the transistor is the source.

In the circuits provided in the embodiments of the present disclosure, a “node” does not represent an actual component, but rather represent a junction of related electrical connections in a circuit diagram. That is to say, the node is a node equivalent to of the junction of the related electrical connections in the circuit diagram.

Hereinafter, the embodiments of the present disclosure will be described by taking an example in which transistors included in respective circuit structures are all N-type transistors.

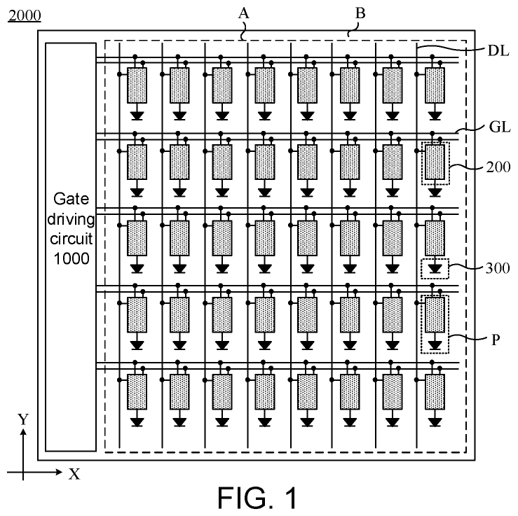

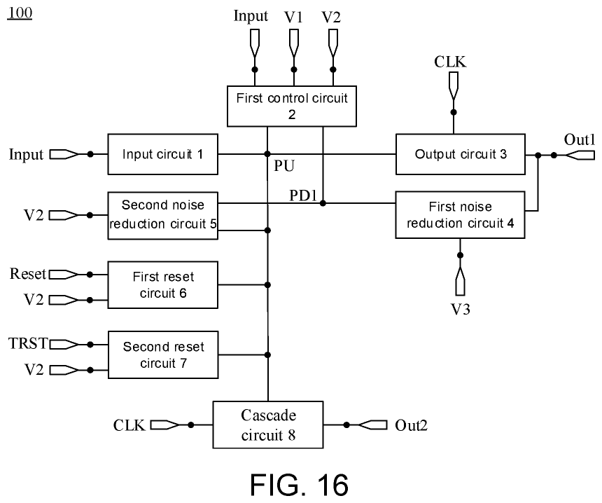

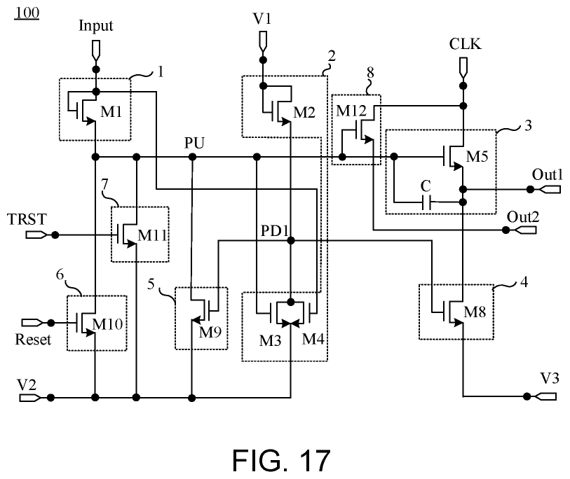

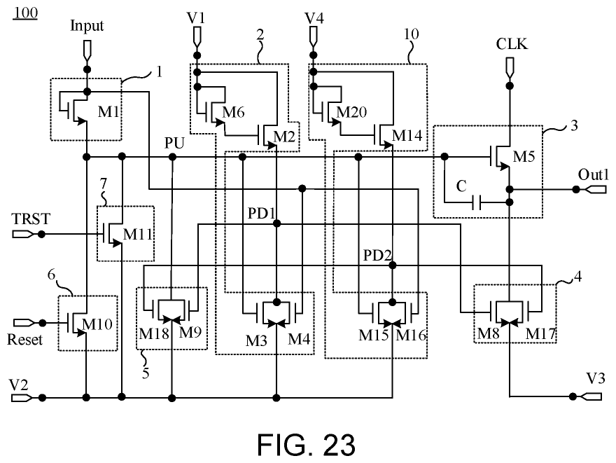

Some embodiments of the present disclosure provide a shift register 100 (as shown in FIGS. 3 to 27) and a control method therefor, a gate driving circuit 1000 (as shown in FIGS. 1 and 29 to 31), and a display panel 2000 (as shown in FIG. 1). Hereafter, the shift register 100 and the control method therefor, the gate driving circuit 1000, and the display panel 2000 will be separately described.

As shown in FIG. 1, some embodiments of the present disclosure provide the display panel 2000. The display panel 2000 may be applied to a display apparatus.

For example, the display apparatus to which the display panel 2000 is applied may be any product or component with a display function, such as a display, a television, a digital camera, a mobile phone or a tablet computer. The display apparatus may be of various types, which may be selectively set according to actual needs.

In some examples, with the development of display technologies, display apparatuses represented by liquid crystal display (LCD) apparatuses are widely used due to their advantages such as high image quality, thin body and low power consumption.

Thin film transistor (TFT) type liquid crystal display apparatuses are common liquid crystal display apparatuses currently. This thin film transistor type liquid crystal display apparatuses use TFTs to drive sub-pixels to display images. The TFT type liquid crystal display apparatuses have advantages such as high responsivity, high brightness and high contrast.

Of course, the display apparatus may also be, for example, a self-luminescent display apparatus. The self-luminescent display apparatus is, for example, an organic light-emitting diode (OLED) display apparatus, a micro light-emitting diode (micro LED) display apparatus, or a mini light-emitting diode (mini LED) display apparatus. The self-luminescent display apparatus is increasingly used in the high-performance display field due to its characteristics such as small size, low power consumption, good display effect, no radiation, and low manufacturing cost.

In some embodiments, as shown in FIG. 1, the display panel 2000 has a display area A and a bezel area B disposed on side(s) of the display area A. The “side(s) of the display area A” refer to one side, two sides, three sides, or a circumferential side of the display area A. That is, the bezel area B may be located on one side, two sides, or three sides of the display area A, or the bezel area B may be disposed around the display area A.

In some examples, as shown in FIG. 1, the display panel 2000 may include a plurality of sub-pixels P, a gate driving circuit 1000, a plurality of gate lines GL extending in a first direction X, and a plurality of data lines DL extending in a second direction Y. The plurality of sub-pixels P may be located in the display area A. At least a part of the gate line GL and at least a part of the data line DL may be located in the display area A.

For example, as shown in FIG. 1, the plurality of sub-pixels P may be uniformly arranged in an array.

For example, sub-pixels P arranged in a line in the first direction X may be referred to as sub-pixels P in a same row, and sub-pixels P arranged in a line in the second direction Y may be referred to as sub-pixels P in a same column. The sub-pixels P in the same row may be electrically connected to at least one gate line GL, and the sub-pixels P in the same column may be electrically connected to one data line DL. The number of gate lines GL electrically connected to the sub-pixels P in the same row may be set based on a structure of the sub-pixels P.

For example, as shown in FIG. 1, the gate driving circuit 1000 may be disposed in the bezel area B and located on a side of the display area A in a direction in which the plurality of gate lines GL extends. The gate driving circuit 1000 may be electrically connected to the plurality of gate lines GL, and may input output signals to the plurality of gate lines GL, so as to drive the plurality of sub-pixels P to display an image. Of course, the gate driving circuit 1000 may also be disposed in the display area A.

For example, the gate driving circuit 1000 may be a gate driver integrated circuit (IC).

For example, the gate driving circuit 1000 may also be a gate driver on array (GOA) circuit. That is, the gate driving circuit 1000 is directly integrated on an array substrate of the display panel 2000.In this case, setting the gate driving circuit 1000 as the GOA circuit may not only reduce a manufacturing cost of the display panel 2000, but also reduce a size of a bezel of the display panel 2000 and achieve a narrow bezel design.

Hereinafter, a description will be given by taking an example in which the gate driving circuit 1000 is the GOA circuit.

In some examples, the sub-pixel P has various structures, which may be selectively set according to actual needs.

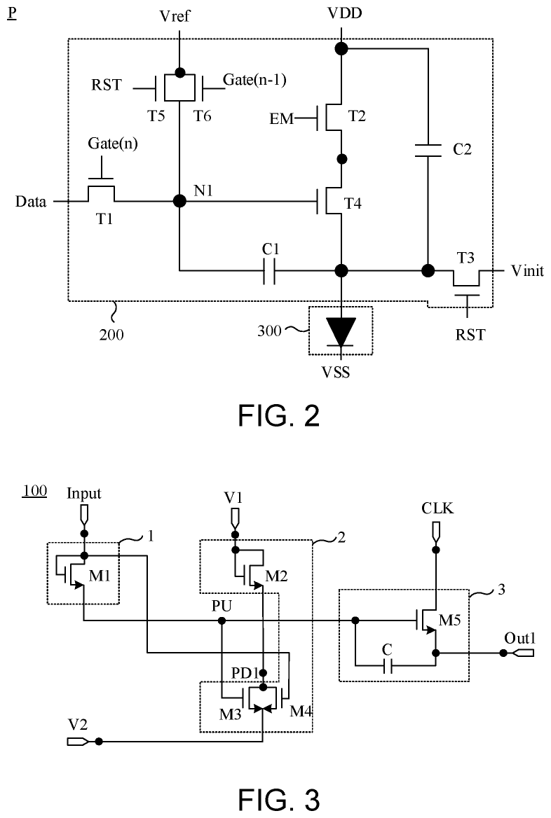

For example, as shown in FIGS. 1 and 2, each sub-pixel P may include a pixel driving circuit 200 and an element 300 to be driven electrically connected to the pixel driving circuit 200. The element 300 to be driven is, for example, a current-driven type light-emitting device.

Further, the current-driven type light-emitting device may be a current-type light-emitting diode. For example, the current-type light-emitting diode may be a micro light-emitting diode, a mini light-emitting diode, an organic light-emitting diode, or a quantum dot light-emitting diode (QLED).

The pixel driving circuit 200 has various structures, which may be selectively set according to actual needs.

For example, the pixel driving circuit 200 may be, for example, any one of a 6T1C pixel driving circuit, a 6T2C pixel driving circuit or a 7T1C pixel driving circuit, or may be a pixel driving circuit of any other type, which is not limited in the present disclosure. Here, “T” represents a transistor, “C” represents a storage capacitor, the number before “T” represents the number of transistors, and the number before “C” represents the number of storage capacitors.

For example, as shown in FIG. 2, the structure and an operation process of the sub-pixel P are schematically described by taking an example in which the pixel driving circuit 200 is the 6T2C pixel driving circuit.

As shown in FIG. 2, the pixel driving circuit 200 may include, for example, a first pixel transistor T1, a second pixel transistor T2, a third pixel transistor T3, a fourth pixel transistor T4, a fifth pixel transistor T5, a sixth pixel transistor T6, a first storage capacitor C1 and a second storage capacitor C2.

A gate of the first pixel transistor T1 is electrically connected to a second scanning signal terminal Gate(n), a first electrode of the first pixel transistor T1 is electrically connected to a data signal terminal Data, and a second electrode of the first pixel transistor T1 is electrically connected to a first node N1. Here, n is greater than or equal to 2 (n≥2), and n is an integer. A gate of the second pixel transistor T2 is electrically connected to an enable signal terminal EM, a first electrode of the second pixel transistor T2 is electrically connected to a power supply voltage signal terminal VDD, and a second electrode of the second pixel transistor T2 is electrically connected to a first electrode of the fourth pixel transistor T4. A gate of the fourth pixel transistor T4 is electrically connected to the first node N1, and a second electrode of the fourth pixel transistor T4 is electrically connected to an anode of the element 300 to be driven. A gate of the third pixel transistor T3 is electrically connected to a reset signal terminal RST, a first electrode of the third pixel transistor T3 is electrically connected to an initial signal terminal Vinit, and a second electrode of the third pixel transistor T3 is electrically connected to the anode of the element 300 to be driven. A gate of the fifth pixel transistor T5 is electrically connected to the reset signal terminal RST, a first electrode of the fifth pixel transistor T5 is electrically connected to a reference voltage signal terminal Vref, and a second electrode of the fifth pixel transistor T5 is electrically connected to the first node N1. A gate of the sixth pixel transistor T6 is electrically connected to a first scanning signal terminal Gate(n-1), a first electrode of the sixth pixel transistor T6 is electrically connected to the reference voltage signal terminal Vref, and a second electrode of the sixth pixel transistor T6 is electrically connected to the first node N1. A first terminal of the first storage capacitor C1 is electrically connected to the first node N1, and a second terminal of the first storage capacitor C1 is electrically connected to the anode of the element 300 to be driven. A first terminal of the second storage capacitor C2 is electrically connected to the power supply voltage signal terminal VDD, and a second terminal of the second storage capacitor C2 is electrically connected to the second electrode of the third pixel transistor T3. A cathode of the element 300 to be driven is electrically connected to a ground terminal VSS.

The first storage capacitor C1 and the second storage capacitor C2 are each used to store charge and maintain voltage. The first storage capacitor C1 is used to maintain a voltage of the first node N1, so that the fourth pixel transistor T4 may be maintained in a turn-on state; the second storage capacitor C2 is used to maintain a voltage of the anode of the element 300 to be driven after the fourth pixel transistor T4 is turned off, so that the element 300 to be driven may continue to emit light for a period of time after the fourth pixel transistor T4 is turned off.

For an nth row of sub-pixels P (i.e., any row of sub-pixels P except a first row of sub-pixels P), in a first phase, the sixth pixel transistor T6 is turned on under control of a first scanning signal transmitted by the first scanning signal terminal Gate(n-1), and writes a reference voltage signal received at the reference voltage signal terminal Vref into the first node N1. In a second phase, the first pixel transistor T1 is turned on under control of a second scanning signal transmitted by the second scanning signal terminal Gate(n), and writes a data signal received at the data signal terminal Data into the first node N1. The fourth pixel transistor T4 is turned on due to action of the data signal and the reference voltage signal, and the fourth pixel transistor T4 may be referred to as a driving transistor. In a third phase, the second pixel transistor T2 is turned on under control of an enable signal transmitted by the enable signal terminal EM, and transmits a first voltage signal received at the power supply voltage signal terminal VDD to the first electrode of the fourth pixel transistor T4. In this way, the fourth pixel transistor T4 drives the element 300 to be driven to emit light due to action of the first voltage signal, the reference voltage signal and the data signal. In a fourth phase, the third pixel transistor T3 is turned on under control of a reset signal transmitted by the reset signal terminal RST, and transmits an initial signal received at the initial signal terminal Vinit to the anode of the element 300 to be driven to reset the element 300 to be driven. The fifth pixel transistor T5 is turned on under the control of the reset signal transmitted by the reset signal terminal RST, and transmits the reference voltage signal received at the reference voltage signal terminal Vref to the first node N1 to reset the first node N1. Thus, display of the nth row of sub-pixels P is completed.

In some embodiments, a structure of the shift register 100 provided in some embodiments of the present disclosure may be as shown in FIGS. 3 to 27. The shift register 100 includes an input circuit 1, a first control circuit 2 and an output circuit 3.

In some examples, as shown in FIGS. 3 to 27, the input circuit 1 is electrically connected to an input signal terminal Input and a pull-up node PU. The input signal terminal Input is used to receive an input signal and transmit the input signal. The input circuit 1 is configured to transmit the input signal received at the input signal terminal Input to the pull-up node PU under control of the input signal transmitted by the input signal terminal Input.

For example, in a case where the input signal is at a high level, the input circuit 1 may be turned on under the control of the input signal, receive the input signal, and transmit the input signal to the pull-up node PU, so as to charge the pull-up node PU.

For example, in a case where the plurality of shift registers 100 connected in cascade form the gate driving circuit 1000, an input signal terminal Input of a first shift register 100 in the gate driving circuit 1000 may be, for example, electrically connected to a start signal terminal Stvp, and an input signal received by the first shift register 100 is a start signal received at the start signal terminal Stvp.

In some examples, as shown in FIGS. 3 to 27, the first control circuit 2 is electrically connected to a first voltage signal terminal V1, the pull-up node PU, a first pull-down node PD1, and a second voltage signal terminal V2. The first voltage signal terminal V1 is used to receive a first voltage signal and transmit the first voltage signal to the first control circuit 2. The second voltage signal terminal V2 is used to receive a second voltage signal and transmit the second voltage signal. The first control circuit 2 is configured to: transmit the first voltage signal received at the first voltage signal terminal V1 to the first pull-down node PD1 under control of the first voltage signal transmitted by the first voltage signal terminal V1, and transmit the second voltage signal received at the second voltage signal terminal V2 to the first pull-down node PD1 under control of a voltage of the pull-up node PU.

Here, the first voltage signal and the second voltage signal are different. For example, a level of the first voltage signal remains unchanged in a display period of a frame, and the first voltage signal is, for example, a direct current (DC) high-level signal. The second voltage signal is, for example, a DC low-level signal.

For example, in a case where the first voltage signal is at a high level, the first control circuit 2 may be turned on under the control of the first voltage signal, receive the first voltage signal, and transmit the first voltage signal to the first pull-down node PD1, so as to charge the first pull-down node PD1 and pull up a voltage of the first pull-down node PD1.

For example, in a case where the voltage of the pull-up node PU is at a high level, the first control circuit 2 may be turned on under the control of the voltage of the pull-up node PU, receive the second voltage signal, and transmit the second voltage signal to the first pull-down node PD1, so as to pull down the voltage of the first pull-down node PD1.

It is worth mentioning that, during operation of the shift register 100, the voltage of the pull-up node PU and the voltage of the first pull-down node PD1 are always inverted voltages. That is to say, the voltage of the pull-up node PU and the voltage of the first pull-down node PD1 are always one at a high level and the other at a low level. For example, in a case where the voltage of the pull-up node PU is at a high level, the voltage of the first pull-down node PD1 is at a low level; in a case where the voltage of the pull-up node PU is at a low level, the voltage of the first pull-down node PD1 is at a high level.

For the shift register 100 in the embodiments of the present disclosure, since the level of the first voltage signal remains unchanged in the display period of the frame, the first control circuit 2 continuously transmits the high-level first voltage signal to the first pull-down node PD1. In this case, when the voltage of the pull-up node PU is at a high level, the first control circuit 2 may transmit the low-level second voltage signal to the first pull-down node PD1 while transmitting the high-level first voltage signal to the first pull-down node PD1, so as to pull down the voltage of the first pull-down node PD1 by using the second voltage signal. In a case where the voltage of the pull-up node PU is at a low level, the first control circuit 2 does not transmit the low-level second voltage signal to the first pull-down node PD1, so that the voltage of the first pull-down node PD1 is at a high level.

In some examples, as shown in FIGS. 3 to 27, the output circuit 3 is electrically connected to the pull-up node PU, a clock signal terminal CLK and a first output signal terminal Out1. The clock signal terminal CLK is used to receive a clock signal and transmit the clock signal. The output circuit 3 is configured to transmit the clock signal received at the clock signal terminal CLK to the first output signal terminal Out1 under the control of the voltage of the pull-up node PU.

For example, in a case where the voltage of the pull-up node PU is at a high level, the output circuit 3 may be turned on under the control of the voltage of the pull-up node PU, receive the clock signal, and transmit the clock signal to the first output signal terminal Out1. The first output signal terminal Out1 may output the clock signal as a first output signal.

Here, the first output signal terminal Out1 may be electrically connected to sub-pixels P in a corresponding row in the display panel 2000, and transmit the first output signal to the sub-pixels P in the corresponding row to drive the sub-pixels P in the corresponding row to perform display scanning.

It will be noted that, characteristics of transistors in the shift register 100 may be affected by changes in temperature. For example, threshold voltages of the transistors may change with the changes in temperature. At a high temperature, the characteristics of the transistors tend to deteriorate, and turn-on voltages thereof tend to become low; and at a low temperature, the turn-on voltages of the transistors tend to become high.

Based on this, if the shift register 100 is used in a high temperature environment, after the characteristics of the transistors deteriorate, a competition relationship tends to occur between the pull-up node PU and the first pull-down node PD1. After the pull-up node PU is charged for a period of time, the first control circuit 2 receives the second voltage signal and transmits the second voltage signal to the first pull-down node PD1 under the control of the voltage of the pull-up node PU, resulting in a phenomenon of abnormal display of the display panel 2000 to which the shift register 100 is applied. If the shift register 100 is used in a low temperature environment, the turn-on voltages of the transistors become high, which leads to a poor startup performance of the shift register 100.

Therefore, if the shift register 100 is applied in the high temperature environment, the competition relationship between the first pull-down node PD1 and the pull-up node PU needs to be improved or even eliminated to reduce display abnormalities of an image. The display abnormalities include, for example, a splash screen, black lines, a black screen and other abnormalities. If the shift register 100 is used in the low temperature environment, a pre-charging capability of the pull-up node PU needs to be improved to ensure that the output circuit 3 may be normally turned on, and the first output signal terminal Out1 may normally output the first output signal, so as to improve a problem of the poor startup performance of the shift register 100 in the low temperature environment.

Based on this, as shown in FIGS. 3 to 27, in the shift register 100 provided in the embodiments of the present disclosure, the first control circuit 2 is further electrically connected to the input signal terminal Input.

In some examples, the first control circuit 2 is further configured to, in a period when the input circuit 1 transmits the input signal to the pull-up node PU, receive the input signal, and transmit the second voltage signal received at the second voltage signal terminal V2 to the first pull-down node PD1 under the control of the input signal.

For example, in a case where the input signal is at a high level, the input circuit 1 may be turned on under the control of the input signal, and transmit the input signal to the pull-up node PU to charge the pull-up node PU. Meanwhile, the first control circuit 2 may transmit the low-level second voltage signal to the first pull-down node PD1 under the control of the input signal to pull down the voltage of the first pull-down node PD1.

In this way, at a same time when the input circuit 1 is turned on, the first control circuit 2 may receive the second voltage signal and transmit the second voltage signal to the first pull-down node PD1 under the control of the input signal. Therefore, the competition relationship between the pull-up node PU and the first pull-down node PD1 is improved or even eliminated, and it is possible to facilitate to improve the phenomenon of display abnormalities caused by the competition relationship between the pull-up node PU and the first pull-down node PD1.

Based on this, in a process of charging the pull-up node PU by the input circuit 1, it is possible to prevent the pull-up node PU from discharging electricity through other circuit structures (e.g., a second noise reduction circuit 5 mentioned below), and to improve the pre-charging capability of the pull-up node PU. As a result, it is possible to facilitate to improve the problem of the poor startup performance of the shift register 100 in the low temperature environment.

Therefore, for the shift register 100 provided in the embodiments of the present disclosure, by electrically connecting the first control circuit 2 to the input signal terminal Input, the first control circuit 2 can transmit the second voltage signal to the first pull-down node PD1 under the control of the input signal while the input circuit 1 is turned on to charge the pull-up node PU. In this way, the competition relationship between the pull-up node PU and the first pull-down node PD1 is improved or even eliminated. Moreover, the input circuit 1 transmits the input signal to the pull-up node PU and charges the pull-up node PU for a period of time, that is, the first control circuit 2 transmits the second voltage signal to the first pull-down node PD1 for a period of time; then, the first control circuit 2 can also transmit the second voltage signal to the first pull-down node PD1 under the control of the voltage of the pull-up node PU. As a result, the voltage of the first pull-down node PD1 may be pulled down twice in the period when the input circuit 1 transmits the input signal to the pull-up node PU, and the pre-charging capability of the pull-up node PU is improved.

That is to say, the shift register 100 provided in the embodiments of the present disclosure may improve or even eliminate the competition relationship between the pull-up node PU and the first pull-down node PD1, and improve the charging capability of the pull-up node PU. Therefore, it is possible to facilitate to improve or even solve the problem of display abnormalities of the display panel 2000 to which the shift register 100 is applied in the high temperature environment, and the problem of the poor startup performance of the shift register 100 caused by insufficient charging capability of the pull-up node PU in the low temperature environment.

Structures of the input circuit 1, the first control circuit 2 and the output circuit 3 will be schematically described below.

In some examples, as shown in FIGS. 3 to 5, 7, 9, 11, 13, 15, 17, 19, 21, 23, 25 and 27, the input circuit 1 includes a first transistor M1.

For example, as shown in FIGS. 3 to 5, 7, 9, 11, 13, 15, 17, 19, 21, 23, 25 and 27, a gate of the first transistor M1 is electrically connected to the input signal terminal Input, a first electrode of the first transistor M1 is electrically connected to the input signal terminal Input, and a second electrode of the first transistor M1 is electrically connected to the pull-up node PU. The first transistor M1 is configured to transmit the input signal to the pull-up node PU under the control of the input signal transmitted by the input signal terminal Input.

For example, in a case where the input signal is at a high level, the first transistor M1 may be turned on under the control of the input signal, receive the input signal, and transmit the input signal to the pull-up node PU, so as to charge the pull-up node PU.

In some examples, as shown in FIGS. 3 to 5, 7, 9, 11, 13, 15, 17, 19, 21, 23, 25 and 27, the output circuit 3 includes a fifth transistor M5 and a capacitor C.

For example, as shown in FIGS. 3 to 5, 7, 9, 11, 13, 15, 17, 19, 21, 23, 25 and 27, a gate of the fifth transistor M5 is electrically connected to the pull-up node PU, a first electrode of the fifth transistor M5 is electrically connected to the clock signal terminal CLK, and a second electrode of the fifth transistor M5 is electrically connected to the first output signal terminal Out1. The fifth transistor M5 is configured to transmit the clock signal received at the clock signal terminal CLK to the first output signal terminal Out1 under the control of the voltage of the pull-up node PU.

For example, in a case where the voltage of the pull-up node PU is at a high level, the fifth transistor M5 may be turned on under the control of the voltage of the pull-up node PU, receive the clock signal, and transmit the clock signal to the first output signal terminal Out1.

For example, as shown in FIGS. 3 to 5, 7, 9, 11, 13, 15, 17, 19, 21, 23, 25 and 27, a first terminal of the capacitor C is electrically connected to the pull-up node PU, and a second terminal of the capacitor C is electrically connected to the first output signal terminal Out1. The capacitor C is configured to store charge.

For example, when the input circuit 1 is turned on to charge the pull-up node PU, the capacitor C is simultaneously charged. After the input circuit 1 is turned off, the capacitor C discharges electricity, so that the voltage of the pull-up node PU is maintained at a high level, and in turn, the fifth transistor M5 is maintained in a turn-on state.

The first control circuit 2 has various structures, which may be selectively set according to actual needs.

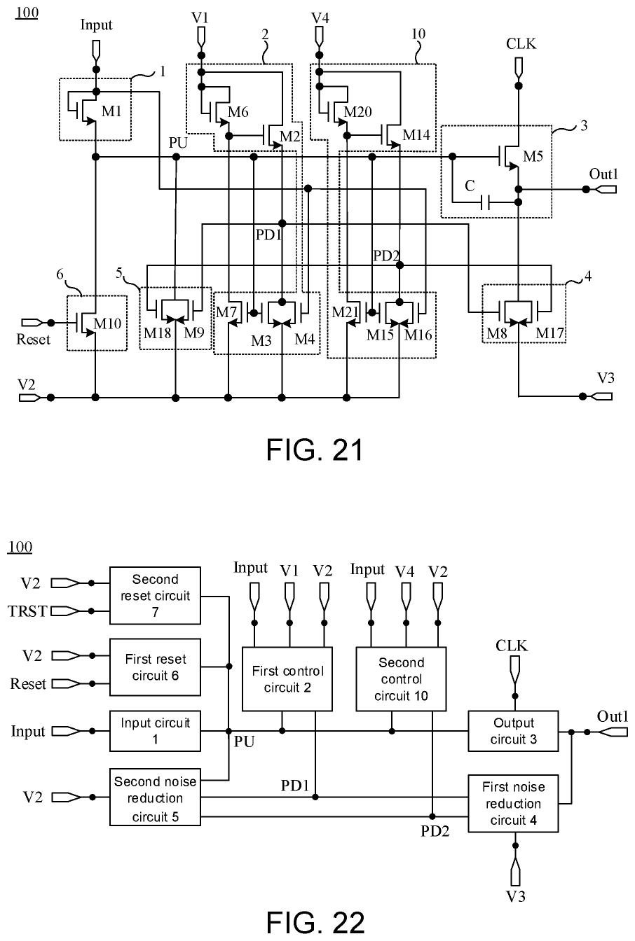

In some examples, as shown in FIGS. 5 and 21, the first control circuit 2 includes a second transistor M2, a third transistor M3, a fourth transistor M4, a sixth transistor M6 and a seventh transistor M7.

For example, as shown in FIGS. 5 and 21, a gate of the sixth transistor M6 is electrically connected to the first voltage signal terminal V1, a first electrode of the sixth transistor M6 is electrically connected to the first voltage signal terminal V1, and a second electrode of the sixth transistor M6 is electrically connected to a gate of the second transistor M2. That is, the gate of the second transistor M2 is electrically connected to the first voltage signal terminal V1 through the sixth transistor M6. A first electrode of the second transistor M2 is electrically connected to the first voltage signal terminal V1, and a second electrode of the second transistor M2 is electrically connected to the first pull-down node PD1. The sixth transistor M6 is configured to transmit the first voltage signal to the gate of the second transistor M2 under the control of the first voltage signal. The second transistor M2 is configured to transmit the first voltage signal to the first pull-down node PD1 under the control of the first voltage signal.

For example, in a case where the first voltage signal is at a high level, the sixth transistor M6 may be turned on under the control of the first voltage signal, receive the first voltage signal, and transmit the first voltage signal to the gate of the second transistor M2; and the second transistor M2 may be turned on under the control of the high-level first voltage signal, receive the first voltage signal, and transmit the first voltage signal to the first pull-down node PD1.

For example, as shown in FIGS. 5 and 21, a gate of the third transistor M3 is electrically connected to the pull-up node PU, a first electrode of the third transistor M3 is electrically connected to the second voltage signal terminal V2, and a second electrode of the third transistor M3 is electrically connected to the first pull-down node PD1. The third transistor M3 is configured to transmit the second voltage signal received at the second voltage signal terminal V2 to the first pull-down node PD1 under the control of the voltage of the pull-up node PU.

For example, in a case where the voltage of the pull-up node PU is at a high level, the third transistor M3 may be turned on under the control of the voltage of the pull-up node PU, receive the second voltage signal, and transmit the second voltage signal to the first pull-down node PD1, so as to pull down the voltage of the first pull-down node PD1.

For example, as shown in FIGS. 5 and 21, a gate of the seventh transistor M7 is electrically connected to the pull-up node PU, a first electrode of the seventh transistor M7 is electrically connected to the second voltage signal terminal V2, and a second electrode of the seventh transistor M7 is electrically connected to the second electrode of the sixth transistor M6. The seventh transistor M7 is configured to transmit the second voltage signal received at the second voltage signal terminal V2 to the second electrode of the sixth transistor M6 under the control of the voltage of the pull-up node PU.

For example, in a case where the voltage of the pull-up node PU is at a high level, the seventh transistor M7 may be turned on under the control of the voltage of the pull-up node PU, receive the second voltage signal, and transmit the second voltage signal to the second electrode of the sixth transistor M6, so that the second transistor M2 is turned off, and does not transmit the first voltage signal to the first pull-down node PD1.

From the above, in a case where the voltage of the pull-up node PU is at a high level, the seventh transistor M7 may be turned on, and transmit the second voltage signal to the second electrode of the sixth transistor M6, so that the second transistor M2 is turned off, and does not transmit the first voltage signal to the first pull-down node PD1; and the third transistor M3 may be turned on, and transmit the second voltage signal to the first pull-down node PD1 to pull down the voltage of the first pull-down node PD1. In a case where the voltage of the pull-up node PU is at a low level, the third transistor M3 and the seventh transistor M7 may be turned off, so that the second voltage signal is not transmitted to the first pull-down node PD1; and the sixth transistor M6 and the second transistor M2 may be turned on, and transmit the first voltage signal to the first pull-down node PD1 to pull up the voltage of the first pull-down node PD1.

For example, as shown in FIGS. 5 and 21, a gate of the fourth transistor M4 is electrically connected to the input signal terminal Input, a first electrode of the fourth transistor M4 is electrically connected to the second voltage signal terminal V2, and a second electrode of the fourth transistor M4 is electrically connected to the first pull-down node PD1. The fourth transistor M4 is configured to transmit the second voltage signal to the first pull-down node PD1 under the control of the input signal transmitted by the input signal terminal Input.

For example, in a case where the input signal is at a high level, the fourth transistor M4 may be turned on under the control of the input signal, receive the second voltage signal, and transmit the second voltage signal to the first pull-down node PD1, so as to pull down the voltage of the first pull-down node PD1.

In a case where the input signal is at a high level, the first transistor M1 and the fourth transistor M4 may be simultaneously turned on under the control of the input signal. The first transistor M1 may transmit the input signal to the pull-up node PU to charge the pull-up node PU. Meanwhile, the fourth transistor M4 may transmit the second voltage signal to the first pull-down node PD1 to pull down the voltage of the first pull-down node PD1. In this way, it is possible to improve or even eliminate the competition relationship between the pull-up node PU and the first pull-down node PD1, and to prevent the pull-up node PU from discharging electricity through other circuit structures (e.g., the second noise reduction circuit 5 mentioned below) in the process of charging the pull-up node PU, and to improve the pre-charging capability of the pull-up node PU.

Here, after the voltage of the pull-up node PU is pulled up to a high level, the third transistor M3 and the fifth transistor M5 may be turned on under the control of the pull-up node PU. The third transistor M3 may transmit the second voltage signal to the first pull-down node PD1, so that the voltage of the first pull-down node PD1 is further pulled down to continue to charge the pull-up node PU. The fifth transistor M5 may transmit the clock signal to the first output signal terminal Out1, so that the first output signal terminal Out1 outputs the first output signal.

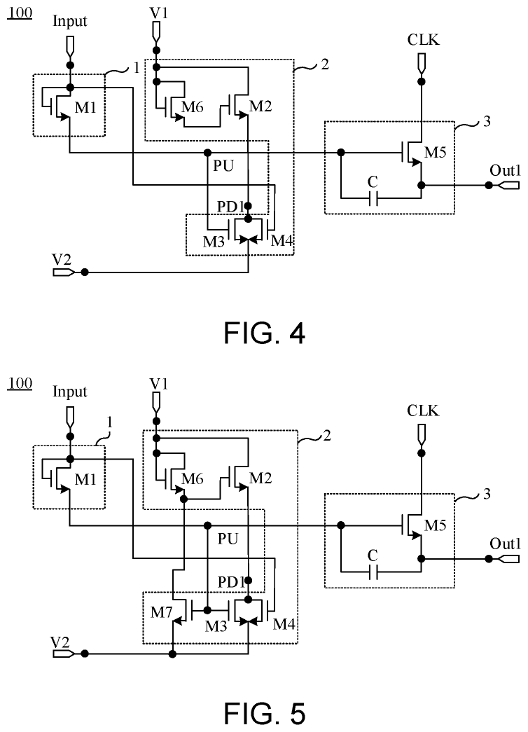

In some other examples, as shown in FIGS. 4 and 23, the first control circuit 2 includes a second transistor M2, a third transistor M3, a fourth transistor M4 and a sixth transistor M6.

For example, as shown in FIGS. 4 and 23, a gate of the sixth transistor M6 is electrically connected to the first voltage signal terminal V1, a first electrode of the sixth transistor M6 is electrically connected to the first voltage signal terminal V1, and a second electrode of the sixth transistor M6 is electrically connected to the gate of the second transistor M2. That is, a gate of the second transistor M2 is electrically connected to the first voltage signal terminal V1 through the sixth transistor M6. A first electrode of the second transistor M2 is electrically connected to the first voltage signal terminal V1, and a second electrode of the second transistor M2 is electrically connected to the first pull-down node PD1. The sixth transistor M6 is configured to transmit the first voltage signal to the gate of the second transistor M2 under the control of the first voltage signal. The second transistor M2 is configured to transmit the first voltage signal to the first pull-down node PD1 under the control of the first voltage signal.

For example, as shown in FIG. 4, a gate of the third transistor M3 is electrically connected to the pull-up node PU, a first electrode of the third transistor M3 is electrically connected to the second voltage signal terminal V2, and a second electrode of the third transistor M3 is electrically connected to the first pull-down node PD1. The third transistor M3 is configured to transmit the second voltage signal received at the second voltage signal terminal V2 to the first pull-down node PD1 under the control of the voltage of the pull-up node PU.

For example, as shown in FIG. 4, a gate of the fourth transistor M4 is electrically connected to the input signal terminal Input, a first electrode of the fourth transistor M4 is electrically connected to the second voltage signal terminal V2, and a second electrode of the fourth transistor M4 is electrically connected to the first pull-down node PD1. The fourth transistor M4 is configured to transmit the second voltage signal to the first pull-down node PD1 under the control of the input signal transmitted by the input signal terminal Input.

In a case where the input signal is at a high level, the first transistor M1 and the fourth transistor M4 may be simultaneously turned on under the control of the input signal. The first transistor M1 may transmit the input signal to the pull-up node PU to charge the pull-up node PU. Meanwhile, the fourth transistor M4 may transmit the second voltage signal to the first pull-down node PD1 to pull down the voltage of the first pull-down node PD1. In this way, it is possible to improve or even eliminate the competition relationship between the pull-up node PU and the first pull-down node PD1, and to prevent the pull-up node PU from discharging electricity through other circuit structures (e.g., the second noise reduction circuit 5 mentioned below) in the process of charging the pull-up node PU, and to improve the pre-charging capability of the pull-up node PU.

Therefore, it facilitates to reduce space occupied by the shift register 100, and in turn to reduce the size of the bezel area B, and to achieve the narrow bezel design of the display panel 2000 to which the shift register 100 is applied.

In yet some other examples, as shown in FIGS. 3, 7, 9, 11, 13, 15, 17, 19, 25 and 27, the first control circuit 2 includes a second transistor M2, a third transistor M3 and a fourth transistor M4.

For example, as shown in FIGS. 3, 7, 9, 11, 13, 15, 17, 19, 25 and 27, a gate of the second transistor M2 is electrically connected to the first voltage signal terminal V1, a first electrode of the second transistor M2 is electrically connected to the first voltage signal terminal V1, and a second electrode of the second transistor M2 is electrically connected to the first pull-down node PD1. The second transistor M2 is configured to transmit the first voltage signal received at the first voltage signal terminal V1 to the first pull-down node PD1 under the control of the first voltage signal transmitted by the first voltage signal terminal V1.

For example, in a case where the first voltage signal is at a high level, the second transistor M2 may be turned on under the control of the first voltage signal, receive the first voltage signal, and transmit the first voltage signal to the first pull-down node PD1, so as to charge the first pull-down node PD1.

For example, as shown in FIGS. 3, 7, 9, 11, 13, 15, 17, 19, 25 and 27, a gate of the third transistor M3 is electrically connected to the pull-up node PU, a first electrode of the third transistor M3 is electrically connected to the second voltage signal terminal V2, and a second electrode of the third transistor M3 is electrically connected to the first pull-down node PD1. The third transistor M3 is configured to transmit the second voltage signal received at the second voltage signal terminal V2 to the first pull-down node PD1 under the control of the voltage of the pull-up node PU.

For example, as shown in FIGS. 3, 7, 9, 11, 13, 15, 17, 19, 25 and 27, a gate of the fourth transistor M4 is electrically connected to the input signal terminal Input, a first electrode of the fourth transistor M4 is electrically connected to the second voltage signal terminal V2, and a second electrode of the fourth transistor M4 is electrically connected to the first pull-down node PD1. The fourth transistor M4 is configured to transmit the second voltage signal to the first pull-down node PD1 under the control of the input signal transmitted by the input signal terminal Input.

In a case where the input signal is at a high level, the first transistor M1 and the fourth transistor M4 may be simultaneously turned on under the control of the input signal. The first transistor M1 may transmit the input signal to the pull-up node PU to charge the pull-up node PU. Meanwhile, the fourth transistor M4 may transmit the second voltage signal to the first pull-down node PD1 to pull down the voltage of the first pull-down node PD1. In this way, it is possible to improve or even eliminate the competition relationship between the pull-up node PU and the first pull-down node PD1, and to prevent the pull-up node PU from discharging electricity through other circuit structures (e.g., the second noise reduction circuit 5 mentioned below) in the process of charging the pull-up node PU, and to improve the pre-charging capability of the pull-up node PU.

Therefore, it facilitates to further reduce the space occupied by the shift register 100, and in turn to further reduce the size of the bezel area B, and to achieve the narrow bezel design of the display panel 2000 to which the shift register 100 is applied.

In addition, the second transistor M2 may be directly turned on under the control of the first voltage signal to directly transmit first voltage signal to the first pull-down node PD1. In this way, a transmission speed of the first voltage signal transmitted to the first pull-down node PD1 may be increased, and the charging capability of the first pull-down node PD1 may be improved.

The impacts of the transistors in the shift register 100 on the pre-charging capability of the pull-up node PU and the charging capability of the first pull-down node PD1 are different. For example, changes in performance of the first transistor M1 and the fourth transistor M4 have a great impact on the pre-charging capability of the pull-up node PU. The faster a speed of the first transistor M1 and the fourth transistor M4 that are turned on under the control of the input signal is, the faster a charging speed of the pull-up node PU is.

For example, selection criteria of the first transistor M1 and the fourth transistor M4 are related to load and voltage of the display panel 2000. The greater the load and the voltage of the display panel 2000 are, the greater channel widths of the first transistor M1 and the fourth transistor M4 may be set. On a premise that channel lengths of the first transistor M1 and the fourth transistor M4 are the same, the greater a channel width of the first transistor M1 is, the greater an on-state current thereof is; and the greater a channel width of the fourth transistor M4 is, the greater an on-state current thereof is. The greater the on-state current of the transistor is, the faster the turn-on speed thereof is.

For the shift register 100, by setting a ratio of a channel width of the second transistor M2 to a channel width of the third transistor M3, a speed at which the third transistor M3 transmits the second voltage signal to the first pull-down node PD1 may be faster than a speed at which the second transistor M2 transmits the first voltage signal to the first pull-down node PD1, so that the voltage of the first pull-down node PD1 may be pulled down as soon as possible.

Optionally, the ratio of the channel width of the second transistor M2 to the channel width of the third transistor M3 may be in a range of 1:5 to 1:15, inclusive.

The second transistor M2 affects the charging capability of the first pull-down node PD1. In a case where the third transistor M3 is turned off, performance of the second transistor M2 determines a charging speed of the first pull-down node PD1. In a case where the third transistor M3 is turned on, the second transistor M2 and the third transistor M3 jointly affect the charging capability of the pull-up node PU.

The third transistor M3 is configured to pull down the voltage of the first pull-down node PD1 under the control of the voltage of the pull-up node PU, so that the charging speed of the pull-up node PU is fast. In this case, the second transistor M2 continuously transmits the first voltage signal to the first pull-down node PD1 to charge the first pull-down node PD1. Therefore, by setting the channel width of the third transistor M3 to be larger than the channel width of the second transistor M2, it is possible to achieve a purpose of pulling down the voltage of the first pull-down node PD1.

In the embodiments of the present disclosure, by setting the ratio of the channel width of the second transistor M2 to the channel width of the third transistor M3 in the range of 1:5 to 1:15, inclusive, the voltage of the first pull-down node PD1 may be maintained at an appropriate level in a case where the voltage of the pull-up node PU is at a high level or a low level, so that the pre-charging capability of the pull-up node PU and the charging capability of the first pull-down node PD1 are improved.

For example, the ratio of the channel width of the second transistor M2 to the channel width of the third transistor M3 may be 1:5, 1:6, 1:9, 1:11, or 1:15.

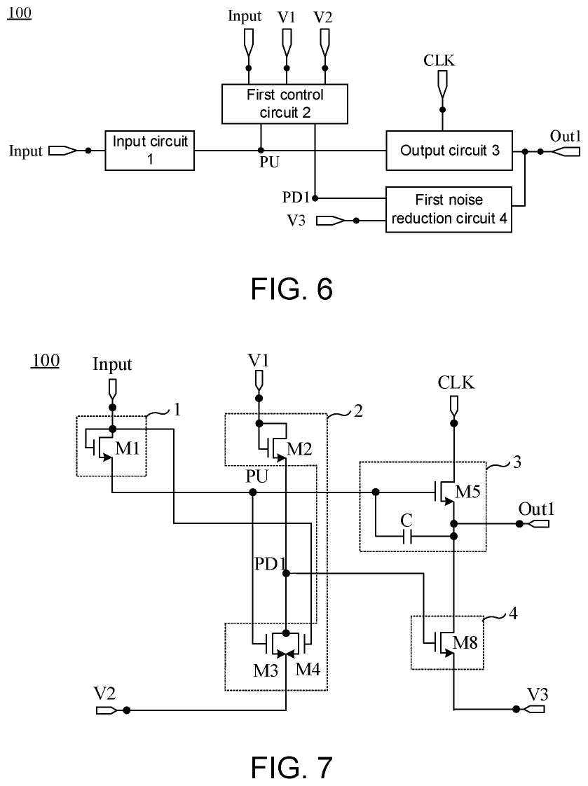

In some embodiments, as shown in FIGS. 6 to 27, the shift register 100 may further include a first noise reduction circuit 4 and/or the second noise reduction circuit 5. That is, the shift register 100 may include the first noise reduction circuit 4; or, the shift register 100 may include the second noise reduction circuit 5; or, the shift register 100 may include the first noise reduction circuit 4 and the second noise reduction circuit 5.

In some examples, as shown in FIGS. 6 to 27, the first noise reduction circuit 4 is electrically connected to the first pull-down node PD1, the first output signal terminal Out1 and a third voltage signal terminal V3. The third voltage signal terminal V3 is used to receive a third voltage signal, and transmit the third voltage signal to the first noise reduction circuit 4. The first noise reduction circuit 4 is configured to transmit the third voltage signal received at the third voltage signal terminal V3 to the first output signal terminal Out1 under control of the voltage of the first pull-down node PD1, so as to reduce noise of the first output signal terminal Out1.

For example, the third voltage signal is a DC low-level signal.

For example, in a case where the voltage of the first pull-down node PD1 is at a high level, the first noise reduction circuit 4 may be turned on under the control of the voltage of the first pull-down node PD1, receive the third voltage signal, and transmit the third voltage signal to the first output signal terminal Out1 to reduce the noise of the first output signal terminal Out1, which avoids affecting accuracy of the first output signal due to that an electrical signal remains at the first output signal terminal Out1.

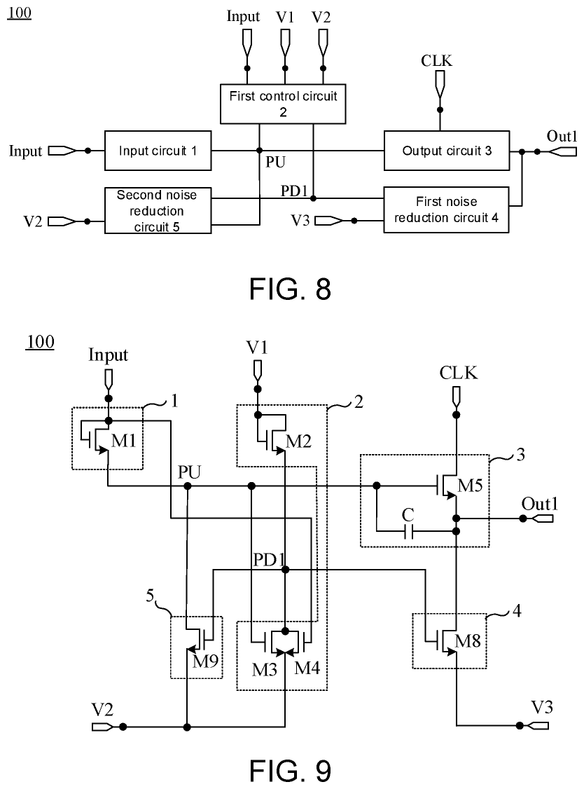

In some examples, as shown in FIGS. 8 to 27, the second noise reduction circuit 5 is electrically connected to the pull-up node PU, the second voltage signal terminal V2 and the first pull-down node PD1. The second noise reduction circuit 5 is configured to transmit the second voltage signal received at the second voltage signal terminal V2 to the pull-up node PU under the control of the voltage of the first pull-down node PD1, so as to reduce noise of the pull-up node PU.

For example, in a case where the voltage of the first pull-down node PD1 is at a high level, the second noise reduction circuit 5 may be turned on under the control of the voltage of the first pull-down node PD1, receive the second voltage signal, and transmit the second voltage signal to the pull-up node PU to reduce the noise of the pull-up node PU, which avoids affecting accuracy of the first output signal output by the output circuit 3 due to that an electrical signal remains at the pull-up node PU.

Structures of the first noise reduction circuit 4 and the second noise reduction circuit 5 will be schematically described below.

In some examples, as shown in FIGS. 7, 9, 11, 13, 15, 17, 19, 21, 23, 25 and 27, the first noise reduction circuit 4 includes an eighth transistor M8.

For example, as shown in FIGS. 7, 9, 11, 13, 15, 17, 19, 21, 23, 25 and 27, a gate of the eighth transistor M8 is electrically connected to the first pull-down node PD1, a first electrode of the eighth transistor M8 is electrically connected to the third voltage signal terminal V3, and a second electrode of the eighth transistor M8 is electrically connected to the first output signal terminal Out1. The eighth transistor M8 is configured to transmit the third voltage signal received at the third voltage signal terminal V3 to the first output signal terminal Out1 under the control of the voltage of the first pull-down node PD1.

For example, in a case where the voltage of the first pull-down node PD1 is at a high level, the eighth transistor M8 may be turned on under the control of the voltage of the first pull-down node PD1, receive the third voltage signal, and transmit the third voltage signal to the first output signal terminal Out1 to pull down a voltage of the first output signal terminal Out1, so as to reduce the noise of the first output signal terminal Out1.

As a result, in a case where the shift register 100 is applied in the high temperature environment, it is possible to facilitate to ensure that the eighth transistor M8 has a good noise reduction effect on the first output signal terminal Out1, and to avoid the problem of display abnormalities.

In some examples, as shown in FIGS. 9, 11, 13, 15, 17, 19, 21, 23, 25 and 27, the second noise reduction circuit 5 includes a ninth transistor M9.

For example, as shown in FIGS. 9, 11, 13, 15, 17, 19, 21, 23, 25 and 27, a gate of the ninth transistor M9 is electrically connected to the first pull-down node PD1, a first electrode of the ninth transistor M9 is electrically connected to the second voltage signal terminal V2, and a second electrode of the ninth transistor M9 is electrically connected to the pull-up node PU. The ninth transistor M9 is configured to transmit the second voltage signal to the pull-up node PU under the control of the voltage of the first pull-down node PD1.

For example, in a case where the voltage of the first pull-down node PD1 is at a high level, the ninth transistor M9 may be turned on under the control of the voltage of the first pull-down node PD1, receive the second voltage signal, and transmit the second voltage signal to the pull-up node PU to pull down the voltage of the pull-up node PU, so as to reduce the noise of the pull-up node PU.

As a result, in the case where the shift register 100 is applied in the high temperature environment, it is possible to facilitate to ensure that the ninth transistor M9 has a good noise reduction effect on the pull-up node PU, and to avoid the problem of display abnormalities.

In a case where the input signal is at a high level, the first transistor M1 and the fourth transistor M4 may be simultaneously turned on. While the first transistor M1 charges the pull-up node PU, the fourth transistor M4 pulls down the voltage of the first pull-down node PD1, so as to prevent the pull-up node PU from discharging electricity through the ninth transistor M9. As a result, the pre-charging capability of the pull-up node PU is improved.

Here, in a case where the second transistor M2 is turned on and transmits the first voltage signal to the first pull-down node PD1 to charge the first pull-down node PD1, and the voltage of the first pull-down node PD1 is pulled up to a high level, the eighth transistor M8 in the first noise reduction circuit 4 and the ninth transistor M9 in the second noise reduction circuit 5 may be simultaneously turned on. The ninth transistor M9 may transmit the second voltage signal to the pull-up node PU to discharge electricity of the pull-up node PU, so as to reduce the noise of the pull-up node PU. The eighth transistor M8 may transmit the third voltage signal to the first output signal terminal Out1 to discharge electricity of the first output signal terminal Out1, so as to reduce the noise of the first output signal terminal Out1.

In some examples, the second voltage signal terminal V2 may be electrically connected to the third voltage signal terminal V3. In this case, the second voltage signal received at the second voltage signal terminal V2 is the same as the third voltage signal received at the third voltage signal terminal V3.

Since the second voltage signal terminal V2 is electrically connected to the third voltage signal terminal V3, the number of signal lines in the shift register 100 may be reduced, which is conducive to simplifying a circuit structure of the shift register 100 and a circuit structure of the gate driving circuit 1000.

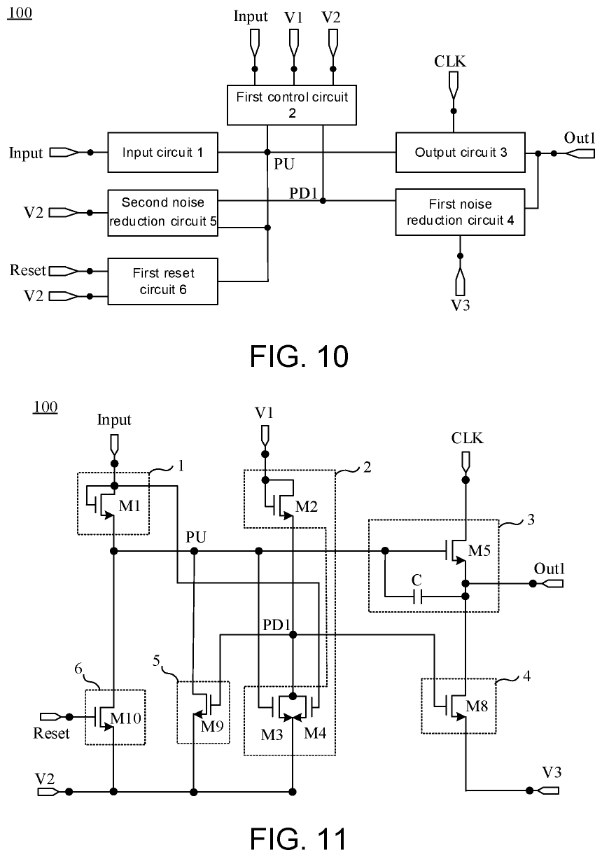

In some embodiments, as shown in FIGS. 10 to 27, the shift register 100 may further include a first reset circuit 6 and/or a second reset circuit 7. That is, the shift register 100 may include the first reset circuit 6; or, the shift register 100 may include the second reset circuit 7; or, the shift register 100 may include the first reset circuit 6 and the second reset circuit 7.

In some examples, as shown in FIGS. 10 to 27, the first reset circuit 6 is electrically connected to the pull-up node PU, a first reset signal terminal Reset and the second voltage signal terminal V2. The first reset signal terminal Reset is used to receive a first reset signal, and transmit the first reset signal to the first reset circuit 6. The first reset circuit 6 is configured to transmit the second voltage signal received at the second voltage signal terminal V2 to the pull-up node PU under control of the first reset signal transmitted by the first reset signal terminal Reset, so as to reset the pull-up node PU.

For example, an effective level of the first reset signal is a high level.

For example, in a case where the first reset signal is at a high level, the first reset circuit 6 may be turned on under the control of the first reset signal, receive the second voltage signal, and transmit the second voltage signal to the pull-up node PU to pull down the voltage of the pull-up node PU, so as to reset the pull-up node PU.

By resetting the pull-up node PU through the first reset circuit 6, that is, by discharging electricity of the pull-up node PU through the first reset circuit 6, the voltage of the pull-up node PU may be changed from a high level to a low level, and in turn, the voltage of the first pull-down node PD1 may be changed from a low level to a high level.

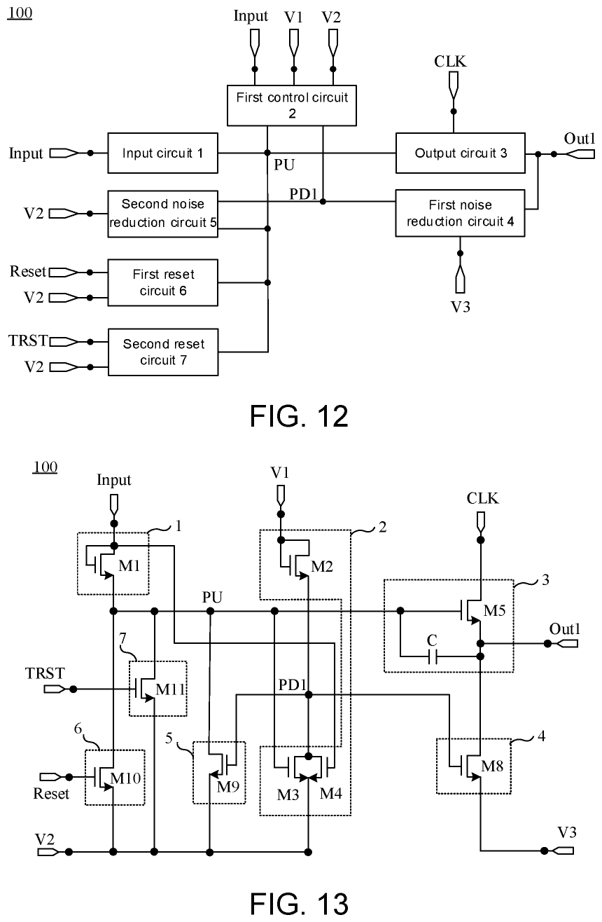

In some examples, as shown in FIGS. 12, 13, 16 to 19, 22, 23, 26 and 27, the second reset circuit 7 is electrically connected to a second reset signal terminal TRST, the pull-up node PU and the second voltage signal terminal V2. The second reset signal terminal TRST is used to receive a second reset signal, and transmit the second reset signal to the second reset circuit 7. The second reset circuit 7 is configured to transmit the second voltage signal received at the second voltage signal terminal V2 to the pull-up node PU under control of the second reset signal transmitted by the second reset signal terminal TRST, so as to reset the pull-up node PU.

For example, an effective level of the second reset signal is a high level.

For example, in a case where the second reset signal is at a high level, the second reset circuit 7 may be turned on under the control of the second reset signal, receive the second voltage signal, and transmit the second voltage signal to the pull-up node PU to pull down the voltage of the pull-up node PU, so as to reset the pull-up node PU, which avoids affecting display of an image due to that the voltage of the pull-up node PU is in an abnormal state during a next operation of the shift register 100.

Optionally, second reset signal terminals TRST of the shift registers 100 included in the gate driving circuit 1000 may be electrically connected together.

In a case where the shift register 100 includes the first reset signal terminal Reset and the second reset signal terminal TRST, the first reset signal is used to control the first reset circuit 6 to reset the pull-up node PU for a first time, and the second reset signal is used to control the second reset circuit 7 to reset the pull-up node PU for a second time, so as to ensure that the pull-up node PU has been reset before next operation. In a case where the shift register 100 includes the second reset signal terminal TRST, all shift registers 100 may be reset at one time through the second reset signal, so that the resetting is convenient and quick, and it is possible to ensure that a last shift register 100 is also reset, and to avoid display abnormalities caused by a problem of charge accumulation at a pull-up node PU in the last shift register 100.

Structures of the first rest circuit 6 and the second reset circuit 7 will be schematically described below.

In some examples, as shown in FIGS. 11, 13, 15, 17, 19, 21, 23, 25 and 27, the first reset circuit 6 includes a tenth transistor M10.

For example, as shown in FIGS. 11, 13, 15, 17, 19, 21, 23, 25 and 27, a gate of the tenth transistor M10 is electrically connected to the first reset signal terminal Reset, a first electrode of the tenth transistor M10 is electrically connected to the second voltage signal terminal V2, and a second electrode of the tenth transistor M10 is electrically connected to the pull-up node PU. The tenth transistor M10 is configured to transmit the second voltage signal received at the second voltage signal terminal V2 to the pull-up node PU under the control of the first reset signal transmitted by the first reset signal terminal Reset.

For example, in a case where the first reset signal is at a high level, the tenth transistor M10 may be turned on under the control of the first reset signal, receive the second voltage signal, and transmit the second voltage signal to the pull-up node PU to pull down the voltage of the pull-up node PU, so as to reset the pull-up node PU.

In some examples, as shown in FIGS. 13, 17, 19, 23 and 27, the second reset circuit 7 includes an eleventh transistor M11.

For example, as shown in FIG. 13, a gate of the eleventh transistor M11 is electrically connected to the second reset signal terminal TRST, a first electrode of the eleventh transistor M11 is electrically connected to the second voltage signal terminal V2, and a second electrode of the eleventh transistor M11 is electrically connected to the pull-up node PU. The eleventh transistor M11 is configured to transmit the second voltage signal received at the second voltage signal terminal V2 to the pull-up node PU under the control of the second reset signal transmitted by the second reset signal terminal TRST.

For example, in a case where the second reset signal is at a high level, the eleventh transistor M11 may be turned on under the control of the second reset signal, receive the second voltage signal, and transmit the second voltage signal to the pull-up node PU to pull down the voltage of the pull-up node PU, so as to reset the pull-up node PU.

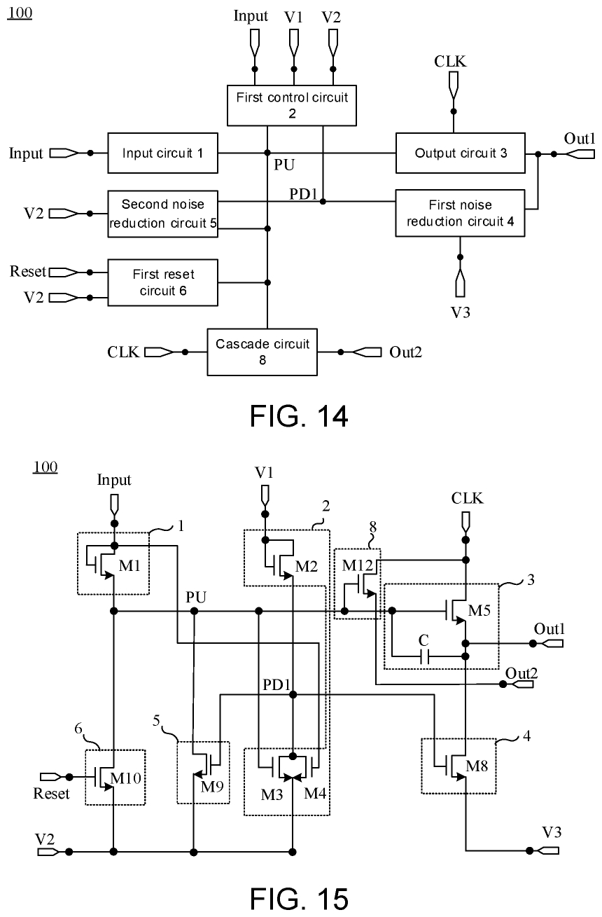

In some embodiments, as shown in FIGS. 14 to 19 and 24 to 27, the shift register 100 further includes a cascade circuit 8.

In some examples, as shown in FIGS. 14 to 19 and 24 to 27, the cascade circuit 8 is electrically connected to the pull-up node PU, the clock signal terminal CLK, and a second output signal terminal Out2. The second output signal terminal Out2 is used to output a second output signal. The cascade circuit 8 is configured to transmit the clock signal received at the clock signal terminal CLK to the second output signal terminal Out2 under the control of the voltage of the pull-up node PU.

For example, in a case where the voltage of the pull-up node PU is at a high level, the cascade circuit 8 may be turned on under the control of the voltage of the pull-up node PU, receive the clock signal, and transmit the clock signal to the second output signal terminal Out2. The second output signal terminal Out2 may output the clock signal as a second output signal.

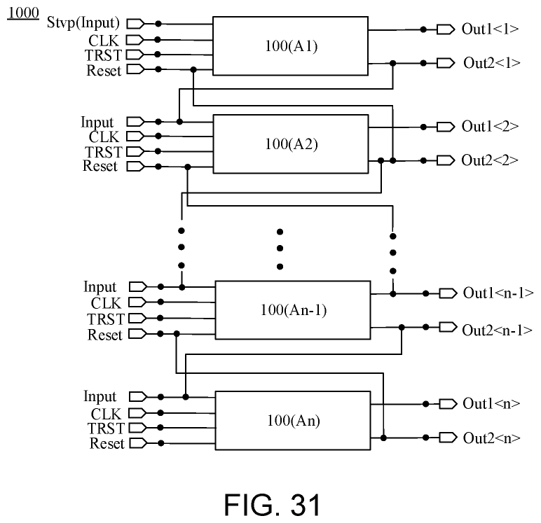

Cascade circuits 8 in the shift registers 100 are used to make the shift registers 100 connected in cascade to form the gate driving circuit 1000. For example, as shown in FIG. 31, except a last shift register 100, a second output signal terminal Out2 of each shift register 100 may be electrically connected to an input signal terminal Input of a next shift register 100. In this case, a second output signal output by the second output signal terminal Out2 of each shift register 100 may be used as an input signal of the next shift register 100. Except a first shift register 100, the second output signal terminal Out2 of each shift register 100 may be electrically connected to a first reset signal terminal Reset of a previous shift register 100. In this case, the second output signal output by the second output signal terminal Out2 of each shift register 100 may be used as a first reset signal of the previous shift register 100. Except the first shift register 100 and the last shift register 100, the second output signal terminal Out2 of each shift register 100 is electrically connected to the first reset signal terminal Reset of the previous shift register 100, and the input signal terminal Input of the next shift register 100.

Here, the cascade circuits 8 are used to achieve that the shift registers 100 are connected in cascade, and loads (e.g., a previous shift register 100 and a next shift register 100) connected to a second output signal terminal Out2 are few, so that stability and accuracy of the second output signal output by the second output signal terminal Out2 are high. Therefore, the cascade circuits 8 achieves that the shift registers 100 are connected in cascade, and it is possible to ensure stability and accuracy of signals output by the shift registers 100, and in turn to improve operation performance of the gate driving circuit 1000.

It can be noted that, in a case where the shift register 100 does not include the cascade circuit 8, the shift registers 100 may be connected in cascade through first output signal terminals Out1 thereof.

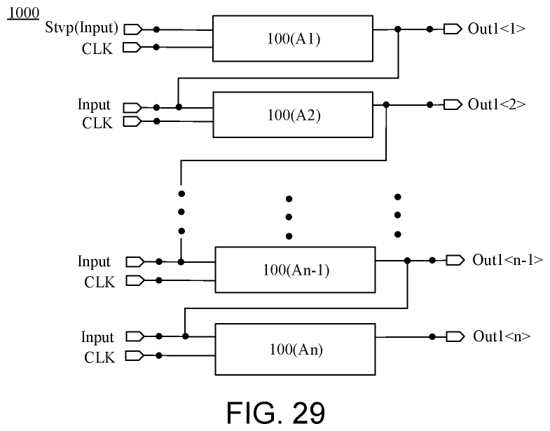

For example, as shown in FIG. 29, except the last shift register 100, a first output signal terminal Out1 of each shift register 100 is electrically connected to an input signal terminal Input of a next shift register 100. In this case, a first output signal output by the first output signal terminal Out1 of each shift register 100 may be used as an input signal of the next shift register 100.

For example, in a case where the shift register 100 includes the first reset signal terminal Reset, except the last shift register 100, a first output signal terminal Out1 of each shift register 100 may be electrically connected to an input signal terminal Input of a next shift register 100. In this case, a first output signal output by the first output signal terminal Out1 of each shift register 100 may be used as an input signal of the next shift register 100. Except the first shift register 100, the first output signal terminal Out1 of each shift register 100 may be electrically connected to a first reset signal terminal Reset of a previous shift register 100. In this case, the first output signal output by the first output signal terminal Out1 of each shift register 100 may be used as a first reset signal of the previous shift register 100. Except the first shift register 100 and the last shift register 100, a first output signal terminal Out1 of each shift register 100 is electrically connected to a first reset signal terminal Reset of a previous shift register 100 and an input signal terminal Input of a next shift register 100.

For example, the shift register 100 may transmit output signal(s) to pixel driving circuits 200, a first reset signal terminal Reset of a previous shift register 100, and an input signal terminal Input of a next shift register 100. The output signal(s) include, for example, the first output signal. In a case where the shift register 100 further includes the second output signal terminal Out2, the output signal(s) include, for example, the first output signal and the second output signal. The first output signal is transmitted to the pixel driving circuits 200, and the second output signal is transmitted to the first reset signal terminal Reset of the previous shift register 100 and the input signal terminal Input of the next shift register 100.

A structure of the cascade circuit 8 will be schematically described below.

In some examples, as shown in FIGS. 15, 17, 19, 25 and 27, the cascade circuit 8 includes a twelfth transistor M12.

For example, as shown in FIG. 15, a gate of the twelfth transistor M12 is electrically connected to the pull-up node PU, a first electrode of the twelfth transistor M12 is electrically connected to the clock signal terminal CLK, and a second electrode of the twelfth transistor M12 is electrically connected to the second output signal terminal Out2. The twelfth transistor M12 is configured to transmit the clock signal received at the clock signal terminal CLK to the second output signal terminal Out2 under the control of the voltage of the pull-up node PU.

For example, in a case where the voltage of the pull-up node PU is at a high level, the twelfth transistor M12 may be turned on under the control of the voltage of the pull-up node PU, receive the clock signal, and transmit the clock signal to the second output signal terminal Out2, so that the second output signal terminal Out2 outputs the clock signal as the second output signal.

For example, a waveform of the second output signal is the same as a waveform of the first output signal.

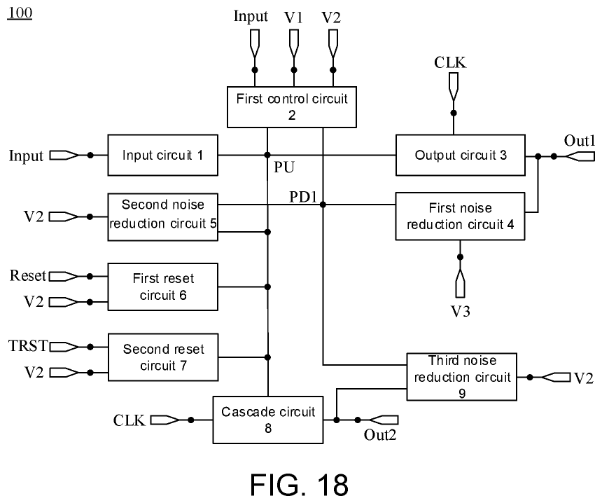

In some embodiments, as shown in FIGS. 18, 19 and 24 to 27, the shift register 100 further includes a third noise reduction circuit 9.

In some examples, as shown in FIGS. 18, 19, and 24 to 27, the third noise reduction circuit 9 is electrically connected to the first pull-down node PD1, the second output signal terminal Out2 and the second voltage signal terminal V2. The third noise reduction circuit 9 is configured to transmit the second voltage signal received at the second voltage signal terminal V2 to the second output signal terminal Out2 under the control of the voltage of the first pull-down node PD1, so as to reduce noise of the second output signal terminal Out2.

For example, in a case where the voltage of the first pull-down node PD1 is at a high level, the third noise reduction circuit 9 may be turned on under the control of the voltage of the first pull-down node PD1, receive the second voltage signal, and transmit the second voltage signal to the second output signal terminal Out2, so as to reduce the noise of the second output signal terminal Out2, which avoids affecting accuracy of the second output signal output by the cascade circuit 8 due to that an electrical signal remains at the second output signal terminal Out2.

A structure of the third noise reduction circuit 9 will be schematically described below.

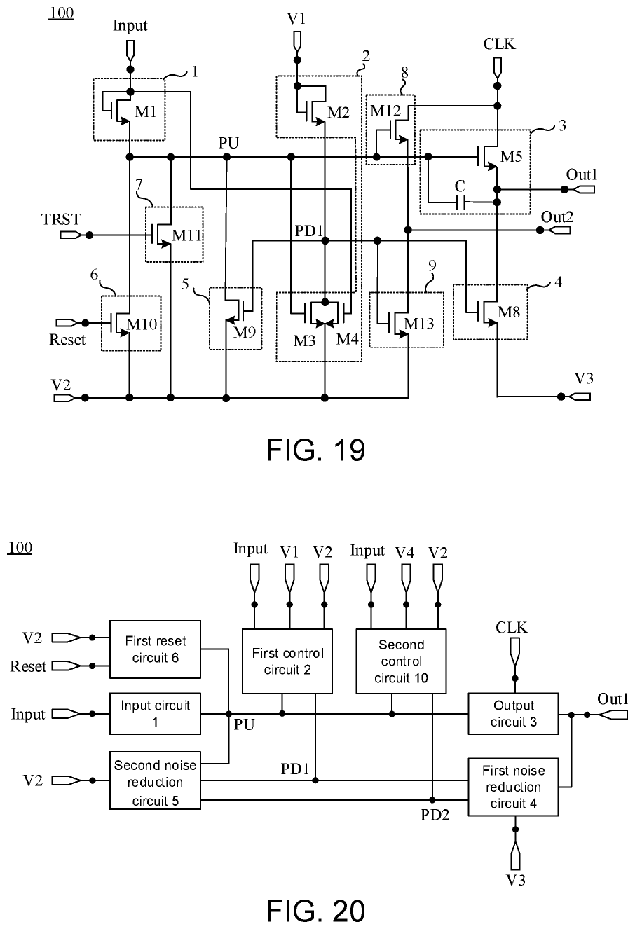

In some examples, as shown in FIGS. 19, 25 and 27, the third noise reduction circuit 9 includes a thirteenth transistor M13.

For example, as shown in FIG. 19, a gate of the thirteenth transistor M13 is electrically connected to the first pull-down node PD1, a first electrode of the thirteenth transistor M13 is electrically connected to the second voltage signal terminal V2, and a second electrode of the thirteenth transistor M13 is electrically connected to the second output signal terminal Out2. The thirteenth transistor M13 is configured to transmit the second voltage signal received at the second voltage signal terminal V2 to the second output signal terminal Out2 under the control of the voltage of the first pull-down node PD1.

For example, in a case where the voltage of the first pull-down node PD1 is at a high level, the thirteenth transistor M13 may be turned on under the control of the voltage of the first pull-down node PD1, receive the second voltage signal, and transmit the second voltage signal to the second output signal terminal Out2 to pull down a voltage of the second output signal terminal Out2, so as to reduce the noise of the second output signal terminal Out2.

For example, a second output signal terminal Out2 of a shift register 100 is used to be electrically connected to a first reset signal terminal Reset of a previous shift register 100, and an input signal terminal Input of a next shift register 100, so that the shift registers 100 connected in cascade is achieved.

In a case where the third noise reduction circuit 9 electrically connected to the second output signal terminal Out2 is provided, the shift registers 100 that are connected in cascade is achieved through the cascade circuits 8, so that it is possible to ensure accuracy and stability of signals transmitted to the previous shift register 100 and the next shift register 100.

In some embodiments, as shown in FIGS. 20 to 27, the shift register 100 further includes a second control circuit 10.

In some examples, as shown in FIGS. 20 to 27, the second control circuit 10 is electrically connected to a fourth voltage signal terminal V4, the pull-up node PU, a second pull-down node PD2, and the second voltage signal terminal V2. The fourth voltage signal terminal V4 is used to receive a fourth voltage signal, and transmit the fourth voltage signal to the second control circuit 10. The second control circuit 10 is configured to: transmit the fourth voltage signal received at the fourth voltage signal terminal V4 to the second pull-down node PD2 under control of the fourth voltage signal transmitted by the fourth voltage signal terminal V4; and transmit the second voltage signal received at the second voltage signal terminal V2 to the second pull-down node PD2 under the control of the voltage of the pull-up node PU.

For example, in a case where the fourth voltage signal is at a high level, the second control circuit 10 may be turned on under the control of the fourth voltage signal, and transmit the fourth voltage signal to the second pull-down node PD2, so as to charge the second pull-down node PD2, and to pull up a voltage of the second pull-down node PD2.

For example, in a case where the voltage of the pull-up node PU is at a high level, the second control circuit 10 may be turned on under the control of the voltage of the pull-up node PU, receive the second voltage signal, and transmit the second voltage signal to the second pull-down node PD2, so as to pull down the voltage of the second pull-down node PD2.

In some examples, as shown in FIGS. 20 to 27, the second control circuit 10 is further electrically connected to the input signal terminal Input. The second control circuit 10 is further configured to, in the period when the input circuit 1 transmits the input signal to the pull-up node PU, receive the input signal, and transmit the second voltage signal to the second pull-down node PD2 under the control of the input signal.

For example, in a case where the input signal is at a high level, the input circuit 1 may be turned on under the control of the input signal, and transmit the input signal to the pull-up node PU, so as to charge the pull-up node PU. Meanwhile, the second control circuit 10 may transmit the low-level second voltage signal to the second pull-down node PD2 under the control of the input signal, so as to pull down the voltage of the second pull-down node PD2.

For example, the second control circuit 10 and the first control circuit 2 have a same structure and a same operation principle, and achieve same beneficial effects, and details will not be repeated here.

Here, an effective level of the fourth voltage signal is, for example, a high level.

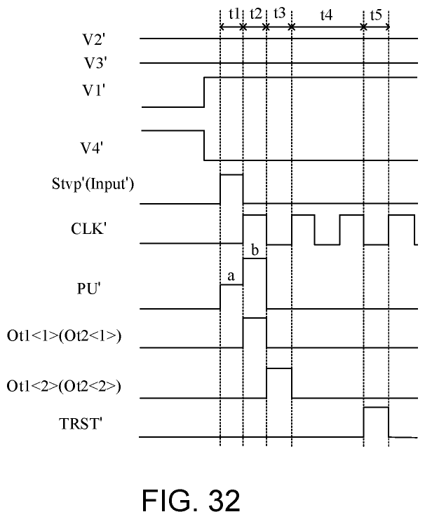

The fourth voltage signal and the first voltage signal are, for example, inverted signals. That is, as shown in FIG. 32, in a case where the fourth voltage signal V4′ is at a high level, the first voltage signal V1′ is at a low level; and in a case where the fourth voltage signal V4′ is at a low level, the first voltage signal V1′ is at a high level.

Here, in the display period of the frame, levels of the fourth voltage signal and the first voltage signal remain unchanged. The level of the fourth voltage signal or the level of the first voltage signal may, for example, change (from a high level to a low level or from a low level to a high level) between display periods in two adjacent frames.

The fourth voltage signal terminal V4 and the first voltage signal terminal V1 have the same function, and control the second control circuit 10 and the first control circuit 2 alternately operate. Since the second control circuit 10 and the fourth voltage signal terminal V4 are provided, it is possible to prevent the first voltage signal terminal V1 and transistors in the first control circuit 2 from operating for a long time. As a result, it is possible to avoid affecting service lives of transistors in the first control circuit 2 and the second control circuit 10, and to avoid affecting accuracy of the signals output by the transistors in the first control circuit 2 and the second control circuit 10 due to drift of threshold voltages of the transistors in the first control circuit 2 and the second control circuit 10.

In some examples, as shown in FIGS. 20 to 27, in a case where the shift register 100 further includes the first noise reduction circuit 4, the first noise reduction circuit 4 is further electrically connected to the second pull-down node PD2. The first noise reduction circuit 4 is further configured to transmit the third voltage signal received at the third voltage signal terminal V3 to the first output signal terminal Out1 under control of a voltage of the second pull-down node PD2, so as to reduce the noise of the first output signal terminal Out1.

For example, in a case where the voltage of the second pull-down node PD2 is at a high level, the first noise reduction circuit 4 may be turned on under the control of the voltage of the second pull-down node PD2, receive the third voltage signal, and transmit the third voltage signal to the first output signal terminal Out1, so as to reduce the noise of the first output signal terminal Out1, and to avoid affecting the accuracy of the first output signal output by the output circuit 3 due to that an electrical signal remains at the first output signal terminal Out1.

In some examples, as shown in FIGS. 20 to 27, in a case where the shift register 100 further includes the second noise reduction circuit 5, the second noise reduction circuit 5 is further electrically connected to the second pull-down node PD2. The second noise reduction circuit 5 is further configured to transmit the second voltage signal received at the second voltage signal terminal V2 to the pull-up node PU under the control of the voltage of the second pull-down node PD2, so as to reduce the noise of the pull-up node PU.

For example, in a case where the voltage of the second pull-down node PD2 is at a high level, the second noise reduction circuit 5 may be turned on under the control of the voltage of the second pull-down node PD2, receive the second voltage signal, and transmit the second voltage signal to the pull-up node PU, so as to reduce the noise of the pull-up node PU, and to avoid affecting the accuracy of the first output signal output by the output circuit 3 due to that an electrical signal remains at the pull-up node PU.

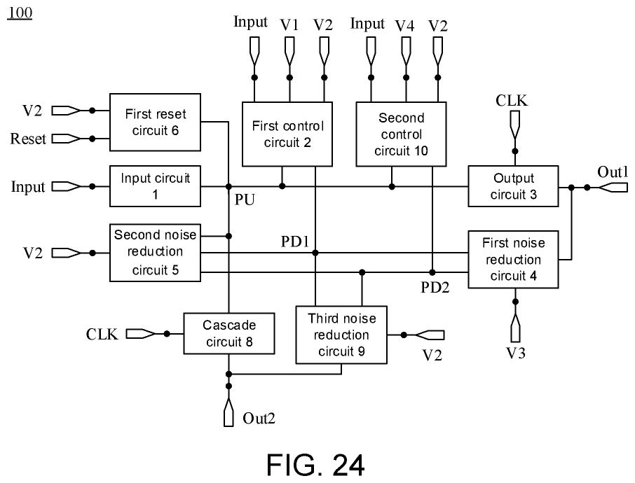

In some examples, as shown in FIGS. 24 to 27, in a case where the shift register 100 further includes the third noise reduction circuit 9, the third noise reduction circuit 9 is further electrically connected to the second pull-down node PD2. The third noise reduction circuit 9 is further configured to transmit the second voltage signal received at the second voltage signal terminal V2 to the second output signal terminal Out2 under the control of the voltage of the second pull-down node PD2, so as to reduce the noise of the second output signal terminal Out2.

For example, in a case where the voltage of the second pull-down node PD2 is at a high level, the third noise reduction circuit 9 may be turned on under the control of the voltage of the second pull-down node PD2, receive the second voltage signal, and transmit the second voltage signal to the second output signal terminal Out2, so as to reduce the noise of the second output signal terminal Out2, and to avoid affecting the accuracy of the second output signal output by the cascade circuit 8 due to that an electrical signal remains at the second output signal terminal Out2.

Here, in a case where the shift register 100 has the second pull-down node PD2, when the second control circuit 10, the first noise reduction circuit 4, the second noise reduction circuit 5, the third noise reduction circuit 9 and other circuits that are electrically connected to the second pull-down node PD2 may each be controlled through the second pull-down node PD2. The first pull-down node PD1 and the second pull-down node PD2 operate alternately, which may cause drift of threshold voltages of transistors in respective circuit to be reduced, and service lives of the transistors in respective circuit to be prolonged.

Structures of the second control circuit 10, the first noise reduction circuit 4, the second noise reduction circuit 5 and the third noise reduction circuit 9 will be schematically described below.

The second control circuit 10 may have various structures, which may be selectively set according to actual needs.

In some examples, as shown in FIG. 21, the second control circuit 10 includes a fourteenth transistor M14, a fifteenth transistor M15, a sixteenth transistor M16, a twentieth transistor M20 and a twenty-first transistor M21.

For example, as shown in FIG. 21, a gate of the twentieth transistor M20 is electrically connected to the fourth voltage signal terminal V4, a first electrode of the twentieth transistor M20 is electrically connected to the fourth voltage signal terminal V4, and a second electrode of the twentieth transistor M20 is electrically connected to a gate of the fourteenth transistor M14. That is, the gate of the fourteenth transistor M14 is electrically connected to the fourth voltage signal terminal V4 through the twentieth transistor M20. A first electrode of the fourteenth transistor M14 is electrically connected to the fourth voltage signal terminal V4, and a second electrode of the fourteenth transistor M14 is electrically connected to the second pull-down node PD2. The twentieth transistor M20 is configured to transmit the fourth voltage signal to the gate of the fourteenth transistor M14 under the control of the fourth voltage signal. The fourteenth transistor M14 is configured to transmit the fourth voltage signal to the second pull-down node PD2 under the control of the fourth voltage signal.

For example, in a case where the fourth voltage signal is at a high level, the twentieth transistor M20 may be turned on under the control of the fourth voltage signal, receive the fourth voltage signal, and transmit the fourth voltage signal to the gate of the fourteenth transistor M14. The fourteenth transistor M14 may be turned on under the control of the high-level fourth voltage signal, receive the fourth voltage signal, and transmit the fourth voltage signal to the second pull-down node PD2.

For example, as shown in FIG. 21, a gate of the fifteenth transistor M15 is electrically connected to the pull-up node PU, a first electrode of the fifteenth transistor M15 is electrically connected to the second voltage signal terminal V2, and a second electrode of the fifteenth transistor M15 is electrically connected to the second pull-down node PD2. The fifteenth transistor M15 is configured to transmit the second voltage signal received at the second voltage signal terminal V2 to the second pull-down node PD2 under the control of the voltage of the pull-up node PU.

For example, in a case where the voltage of the pull-up node PU is at a high level, the fifteenth transistor M15 may be turned on under the control of the voltage of the pull-up node PU, receive the second voltage signal, and transmit the second voltage signal to the second pull-down node PD2, so as to pull down the voltage of the second pull-down node PD2.

For example, as shown in FIG. 21, a gate of the twenty-first transistor M21 is electrically connected to the pull-up node PU, a first electrode of the twenty-first transistor M21 is electrically connected to the second voltage signal terminal V2, and a second electrode of the twenty-first transistor M21 is electrically connected to the second electrode of the twentieth transistor M20. The twenty-first transistor M21 is configured to transmit the second voltage signal received at the second voltage signal terminal V2 to the second electrode of the twentieth transistor M20 under the control of the voltage of the pull-up node PU.

For example, in a case where the voltage of the pull-up node PU is at a high level, the twenty-first transistor M21 may be turned on under the control of the voltage of the pull-up node PU, receive the second voltage signal, and transmit the second voltage signal to the second electrode of the twentieth transistor M20, so that the fourteenth transistor M14 is turned off, which prevents the fourth voltage signal from being transmitted to the second pull-down node PD2.

For operation processes of the fourteenth transistor M14, the fifteenth transistor M15, the twentieth transistor M20 and the twenty-first transistor M21, reference may be made to operation processes of the second transistor M2, the third transistor M3, the sixth transistor M6 and the seventh transistor M7 in the first control circuit 2, and details will not be repeated here.

For example, as shown in FIG. 21, a gate of the sixteenth transistor M16 is electrically connected to the input signal terminal Input, a first electrode of the sixteenth transistor M16 is electrically connected to the second voltage signal terminal V2, and a second electrode of the sixteenth transistor M16 is electrically connected to the second pull-down node PD2. The sixteenth transistor M16 is configured to transmit the second voltage signal received at the second voltage signal terminal V2 to the second pull-down node PD2 under the control of the input signal.

For example, in a case where the input signal is at a high level, the sixteenth transistor M16 may be turned on under the control of the input signal, receive the second voltage signal, and transmit the second voltage signal to the second pull-down node PD2, so as to pull down the voltage of the second pull-down node PD2, and to improve the pre-charging capability of the pull-up node PU.

Beneficial effects that are achieved by the second control circuit 10 in these examples are the same as beneficial effects that are achieved by the first control circuit 2 shown in FIG. 5, and details will not be repeated here.

In some other examples, as shown in FIG. 23, the second control circuit 10 includes a fourteenth transistor M14, a fifteenth transistor M15, a sixteenth transistor M16 and a twentieth transistor M20.

For example, as shown in FIG. 23, a gate of the twentieth transistor M20 is electrically connected to the fourth voltage signal terminal V4, a first electrode of the twentieth transistor M20 is electrically connected to the fourth voltage signal terminal V4, and a second electrode of the twentieth transistor M20 is electrically connected to a gate of the fourteenth transistor M14. That is, the gate of the fourteenth transistor M14 is electrically connected to the fourth voltage signal terminal V4 through the twentieth transistor M20. A first electrode of the fourteenth transistor M14 is electrically connected to the fourth voltage signal terminal V4, and a second electrode of the fourteenth transistor M14 is electrically connected to the second pull-down node PD2. The twentieth transistor M20 is configured to transmit the fourth voltage signal to the gate of the fourteenth transistor M14 under the control of the fourth voltage signal. The fourteenth transistor M14 is configured to transmit the fourth voltage signal to the second pull-down node PD2 under the control of the fourth voltage signal.

For example, as shown in FIG. 23, a gate of the fifteenth transistor M15 is electrically connected to the pull-up node PU, a first electrode of the fifteenth transistor M15 is electrically connected to the second voltage signal terminal V2, and a second electrode of the fifteenth transistor M15 is electrically connected to the second pull-down node PD2. The fifteenth transistor M15 is configured to transmit the second voltage signal received at the second voltage signal terminal V2 to the second pull-down node PD2 under the control of the voltage of the pull-up node PU.

For example, as shown in FIG. 23, a gate of the sixteenth transistor M16 is electrically connected to the input signal terminal Input, a first electrode of the sixteenth transistor M16 is electrically connected to the second voltage signal terminal V2, and a second electrode of the sixteenth transistor M16 is electrically connected to the second pull-down node PD2. The sixteenth transistor M16 is configured to transmit the second voltage signal received at the second voltage signal terminal V2 to the second pull-down node PD2 under the control of the input signal.

Beneficial effects that are achieved by the second control circuit 10 in these examples are the same as beneficial effects that are achieved by the first control circuit 2 shown in FIG. 4, and details will not be repeated here.

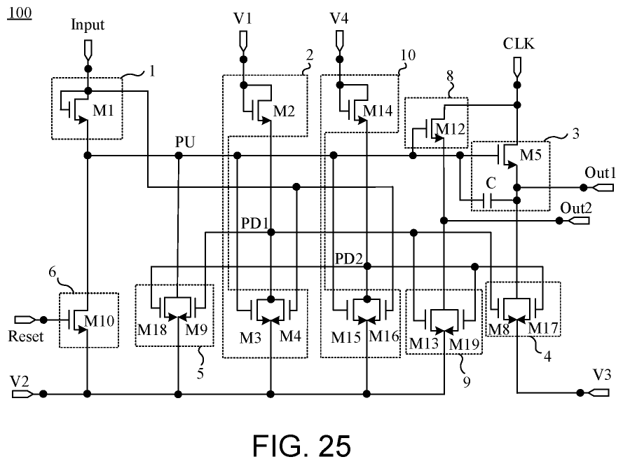

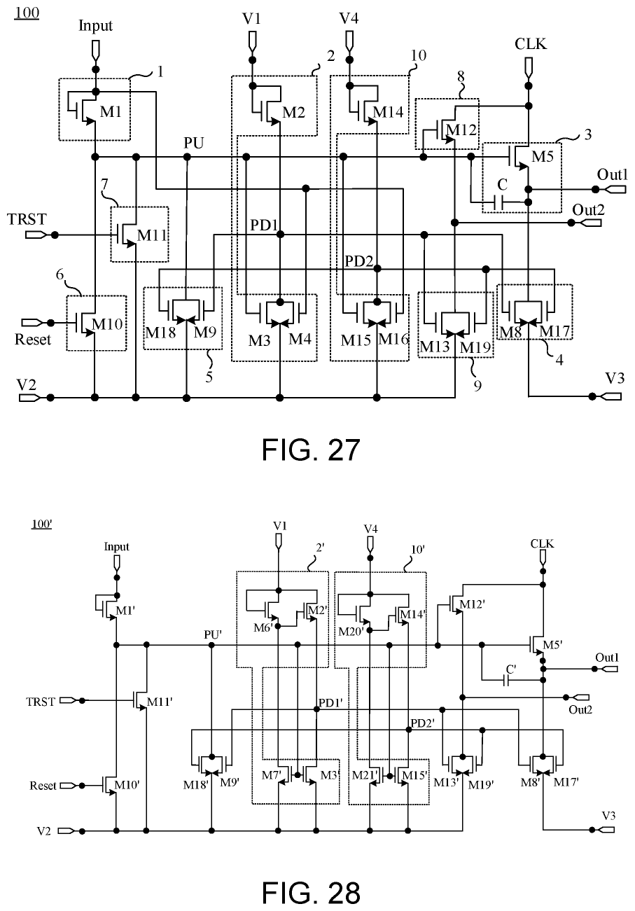

In yet some other examples, as shown in FIGS. 25 and 27, the second control circuit 10 includes a fourteenth transistor M14, a fifteenth transistor M15 and a sixteenth transistor M16.

For example, as shown in FIGS. 25 and 27, a gate of the fourteenth transistor M14 is electrically connected to the fourth voltage signal terminal V4, a first electrode of the fourteenth transistor M14 is electrically connected to the fourth voltage signal terminal V4, and a second electrode of the fourteenth transistor M14 is electrically connected to the second pull-down node PD2. The fourteenth transistor M14 is configured to transmit the fourth voltage signal received at the fourth voltage signal terminal V4 to the second pull-down node PD2 under the control of the fourth voltage signal transmitted by the fourth voltage signal terminal V4.

For example, in a case where the fourth voltage signal is at a high level, the fourteenth transistor M14 may be turned on under the control of the fourth voltage signal, receive the fourth voltage signal, and transmit the fourth voltage signal to the second pull-down node PD2, so as to charge the second pull-down node PD2.

For example, as shown in FIGS. 25 and 27, a gate of the fifteenth transistor M15 is electrically connected to the pull-up node PU, a first electrode of the fifteenth transistor M15 is electrically connected to the second voltage signal terminal V2, and a second electrode of the fifteenth transistor M15 is electrically connected to the second pull-down node PD2. The fifteenth transistor M15 is configured to transmit the second voltage signal received at the second voltage signal terminal V2 to the second pull-down node PD2 under the control of the voltage of the pull-up node PU.

For example, as shown in FIGS. 25 and 27, a gate of the sixteenth transistor M16 is electrically connected to the input signal terminal Input, a first electrode of the sixteenth transistor M16 is electrically connected to the second voltage signal terminal V2, and a second electrode of the sixteenth transistor M16 is electrically connected to the second pull-down node PD2. The sixteenth transistor M16 is configured to transmit the second voltage signal received at the second voltage signal terminal V2 to the second pull-down node PD2 under the control of the input signal.

Beneficial effects that are achieved by the second control circuit 10 in these examples are the same as beneficial effects that are achieved by the first control circuit 2 shown in FIG. 3, and details will not be repeated here.

For example, selection criteria of the sixteenth transistor M16 are the same as the selection criteria of the first transistor M1 and the fourth transistor M4.

Optionally, a width-to-length ratio of the sixteenth transistor M16 is the same as a width-to-length ratio of the fourth transistor M4.

For example, a ratio of a channel width of the fourteenth transistor M14 to a channel width of the fifteenth transistor M15 may be in a range of 1:5 to 1:15, inclusive.

For example, the ratio of the channel width of the fourteenth transistor M14 to the channel width of the fifteenth transistor M15 may be 1:5, 1:6, 1:9, 1:11, or 1:15.

The fourteenth transistor M14 in the second control circuit 10 and the second transistor M2 in the first control circuit 2 operate alternately, so that it is possible to avoid severe drift of threshold voltages and reduction of service lives of the fourteenth transistor M14 and the second transistor M2 caused by that the fourteenth transistor M14 and the second transistor M2 operate for a long time.

For example, a minimum time for which the fourteenth transistor M14 and the second transistor M2 alternately operate is, for example, a display time of a frame. The display time of the frame is, for example, 1/60 s.

Based on this, time for which the fourteenth transistor M14 and the second transistor M2 alternately operate is, for example, in a range of 2 s to 5 s, inclusive. That is, levels of the first voltage signal and the fourth voltage signal change after 2 s to 5 s.

In some examples, as shown in FIGS. 23, 25 and 27, the first noise reduction circuit 4 further includes a seventeenth transistor M17.

For example, as shown in FIGS. 23, 25 and 27, a gate of the seventeenth transistor M17 is electrically connected to the second pull-down node PD2, a first electrode of the seventeenth transistor M17 is electrically connected to the third voltage signal terminal V3, and a second electrode of the seventeenth transistor M17 is electrically connected to the first output signal terminal Out1. The seventeenth transistor M17 is configured to transmit the third voltage signal received at the third voltage signal terminal V3 to the first output signal terminal Out1 under the control of the voltage of the second pull-down node PD2.

For example, in a case where the voltage of the second pull-down node PD2 is at a high level, the seventeenth transistor M17 may be turned on under the control of the voltage of the second pull-down node PD2, receive the third voltage signal, and transmit the third voltage signal to the first output signal terminal Out1 to pull down the voltage of the first output signal terminal Out1, so as to reduce the noise of the first output signal terminal Out1.

Here, the seventeenth transistor M17 and the eighth transistor M8 may operate alternately, so that it is possible to avoid severe drift of threshold voltages and reduction of service lives of the seventeenth transistor M17 and the eighth transistor M8 caused by that the seventeenth transistor M17 and the eighth transistor M8 operate for a long time.

In some examples, as shown in FIGS. 21, 23, 25 and 27, the second noise reduction circuit 5 further includes an eighteenth transistor M18.

For example, as shown in FIGS. 21, 23, 25 and 27, a gate of the eighteenth transistor M18 is electrically connected to the second pull-down node PD2, a first electrode of the eighteenth transistor M18 is electrically connected to the second voltage signal terminal V2, and a second electrode of the eighteenth transistor M18 is electrically connected to the pull-up node PU. The eighteenth transistor M18 is configured to transmit the second voltage signal received at the second voltage signal terminal V2 to the pull-up node PU under the control of the voltage of the second pull-down node PD2.

For example, in a case where the voltage of the second pull-down node PD2 is at a high level, the eighteenth transistor M18 may be turned on under the control of the voltage of the second pull-down node PD2, receive the second voltage signal, and transmit the second voltage signal to the pull-up node PU to pull down the voltage of the pull-up node PU, so as to reduce the noise of the pull-up node PU.

Here, the eighteenth transistor M18 and the ninth transistor M9 may operate alternately, so that it is possible to avoid severe drift of threshold voltages and reduction of service lives of the eighteenth transistor M18 and the ninth transistor M9 caused by that the eighteenth transistor M18 and the ninth transistor M9 operate for a long time.

In some examples, as shown in FIGS. 25 and 27, the third noise reduction circuit 9 further includes a nineteenth transistor M19.

For example, as shown in FIGS. 25 and 27, a gate of the nineteenth transistor M19 is electrically connected to the second pull-down node PD2, a first electrode of the nineteenth transistor M19 is electrically connected to the second voltage signal terminal V2, and a second electrode of the nineteenth transistor M19 is electrically connected to the second output signal terminal Out2. The nineteenth transistor M19 is configured to transmit the second voltage signal received at the second voltage signal terminal V2 to the second output signal terminal Out2 under the control of the voltage of the second pull-down node PD2.

For example, in a case where the voltage of the second pull-down node PD2 is at a high level, the nineteenth transistor M19 may be turned on under the control of the voltage of the second pull-down node PD2, receive the second voltage signal, and transmit the second voltage signal to the second output signal terminal Out2 to pull down the potential at the second output signal terminal Out2, so as to reduce the noise of the second output signal terminal Out2.

Here, the nineteenth transistor M19 and the thirteenth transistor M13 may operate alternately, so that it is possible to avoid severe drift of threshold voltages and reduction of service lives of the nineteenth transistor M19 and the thirteenth transistor M13 caused by that the nineteenth transistor M19 and the thirteenth transistor M13 operate for a long time.

It can be noted that, on a premise that the fourteenth transistor M14 and the second transistor M2 operate alternately, the seventeenth transistor M17 and the eighth transistor M8 operate alternately, the eighteenth transistor M18 and the ninth transistor M9 operate alternately, and the nineteenth transistor M19 and the thirteenth transistor M13 operate alternately. In a case where the fourteenth transistor M14 is turned on to operate, the seventeenth transistor M17, the eighteenth transistor M18, and the nineteenth transistor M19 operate; and in a case where the second transistor M2 is turned on to operate, the eighth transistor M8, the ninth transistor M9 and the thirteenth transistor M13 operate.

A circuit structure of the shift register 100 will be exemplarily described below.

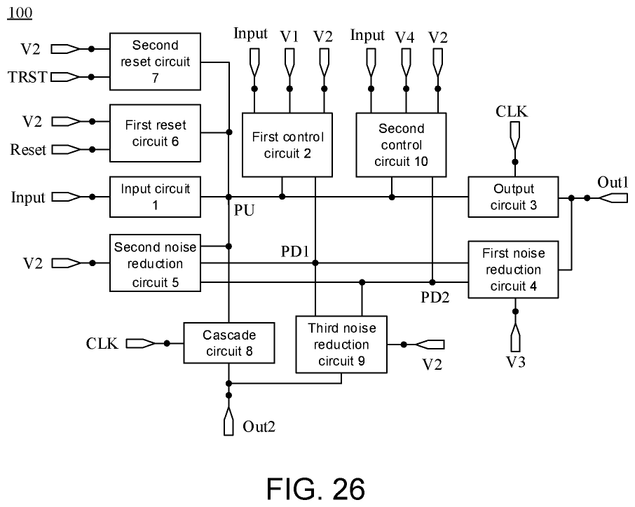

In some examples, as shown in FIG. 26, the shift register 100 includes the input circuit 1, the first control circuit 2, the second control circuit 10, the output circuit 3, the first noise reduction circuit 4, the second noise reduction circuit 5, the first reset circuit 6, the second reset circuit 7, the cascade circuit 8 and the third noise reduction circuit 9.

For example, as shown in FIG. 26, the input circuit 1 is electrically connected to the input signal terminal Input and the pull-up node PU. The input circuit 1 is configured to transmit the input signal to the pull-up node PU under the control of the input signal transmitted by the input signal terminal Input.

For example, as shown in FIG. 26, the first control circuit 2 is electrically connected to the first voltage signal terminal V1, the pull-up node PU, the first pull-down node PD1, and the second voltage signal terminal V2. The first control circuit 2 is configured to: transmit the first voltage signal to the first pull-down node PD1 under the control of the first voltage signal transmitted by the first voltage signal terminal V1; and transmit the second voltage signal received at the second voltage signal terminal V2 to the first pull-down node PD1 under the control of the voltage of the pull-up node PU.

For example, as shown in FIG. 26, the second control circuit 10 is electrically connected to the fourth voltage signal terminal V4, the pull-up node PU, the second pull-down node PD2, and the second voltage signal terminal V2. The second control circuit 10 is configured to: transmit the fourth voltage signal to the second pull-down node PD2 under the control of the fourth voltage signal transmitted by the fourth voltage signal terminal V4; and transmit the second voltage signal received at the second voltage signal terminal V2 to the second pull-down node PD2 under the control of the voltage of the pull-up node PU.

For example, as shown in FIG. 26, the output circuit 3 is electrically connected to the pull-up node PU, the clock signal terminal CLK and the first output signal terminal Out1. The output circuit 3 is configured to transmit the clock signal received at the clock signal terminal CLK to the first output signal terminal Out1 under the control of the voltage of the pull-up node PU.

For example, as shown in FIG. 26, the first noise reduction circuit 4 is electrically connected to the first pull-down node PD1, the second pull-down node PD2, the first output signal terminal Out1 and the third voltage signal terminal V3. The first noise reduction circuit 4 is configured to: transmit the third voltage signal received at the third voltage signal terminal V3 to the first output signal terminal Out1 under the control of the voltage of the first pull-down node PD1, so as to reduce the noise of the first output signal terminal Out1; and transmit the third voltage signal received at the third voltage signal terminal V3 to the first output signal terminal Out1 under the control of the voltage of the second pull-down node PD2, so as to reduce the noise of the first output signal terminal Out1.

For example, as shown in FIG. 26, the second noise reduction circuit 5 is electrically connected to the pull-up node PU, the second pull-down node PD2, the second voltage signal terminal V2 and the first pull-down node PD1. The second noise reduction circuit 5 is configured to: transmit the second voltage signal received at the second voltage signal terminal V2 to the pull-up node PU under the control of the voltage of the first pull-down node PD1, so as to reduce the noise of the pull-up node PU; and transmit the second voltage signal received at the second voltage signal terminal V2 to the pull-up node PU under the control of the voltage of the second pull-down node PD2, so as to reduce the noise of the pull-up node PU.

For example, as shown in FIG. 26, the first reset circuit 6 is electrically connected to the pull-up node PU, the first reset signal terminal Reset, and the second voltage signal terminal V2. The first reset circuit 6 is configured to transmit the second voltage signal received at the second voltage signal terminal V2 to the pull-up node PU under the control of the first reset signal transmitted by the first reset signal terminal Reset, so as to reset the pull-up node PU.

For example, as shown in FIG. 26, the second reset circuit 7 is electrically connected to the second reset signal terminal TRST, the pull-up node PU and the second voltage signal terminal V2. The second reset circuit 7 is configured to transmit the second voltage signal received at the second voltage signal terminal V2 to the pull-up node PU under the control of the second reset signal transmitted by the second reset signal terminal TRST, so as to reset the pull-up node PU.

For example, as shown in FIG. 26, the cascade circuit 8 is electrically connected to the pull-up node PU, the clock signal terminal CLK, and the second output signal terminal Out2. The cascade circuit 8 is configured to transmit the clock signal received at the clock signal terminal CLK to the second output signal terminal Out2 under the control of the voltage of the pull-up node PU.

For example, as shown in FIG. 26, the third noise reduction circuit 9 is electrically connected to the first pull-down node PD1, the second pull-down node PD2, the second output signal terminal Out2 and the second voltage signal terminal V2. The third noise reduction circuit 9 is configured to: transmit the second voltage signal received at the second voltage signal terminal V2 to the second output signal terminal Out2 under the control of the voltage of the first pull-down node PD1, so as to reduce the noise of the second output signal terminal Out2; and transmit the second voltage signal received at the second voltage signal terminal V2 to the second output signal terminal Out2 under the control of the voltage of the second pull-down node PD2, so as to reduce the noise of the second output signal terminal Out2.

As shown in FIG. 26, the first control circuit 2 is further electrically connected to the input signal terminal Input. The first control circuit 2 is further configured to, in the period when the input circuit 1 transmits the input signal to the pull-up node PU, receive the input signal, and transmit the second voltage signal to the first pull-down node PD1 under the control of the input signal.

As shown in FIG. 26, the second control circuit 10 is further electrically connected to the input signal terminal Input. The second control circuit 10 is further configured to, in the period when the input circuit 1 transmits the input signal to the pull-up node PU, receive the input signal, and transmit the second voltage signal to the second pull-down node PD2 under the control of the input signal.

For functions and operation processes of the circuits included in the shift register 100, reference can be made to the description in the embodiments and examples described above, and details will not be repeated here.

Structures of the circuits included in the shift register 100 will be exemplarily described below.

For example, as shown in FIG. 27, the input circuit 1 includes the first transistor M1.

The gate of the first transistor M1 is electrically connected to the input signal terminal Input, the first electrode of the first transistor M1 is electrically connected to the input signal terminal Input, and the second electrode of the first transistor M1 is electrically connected to the pull-up node PU.

For example, as shown in FIG. 27, the first control circuit 2 includes the second transistor M2, the third transistor M3 and the fourth transistor M4.

The gate of the second transistor M2 is electrically connected to the first voltage signal terminal V1, the first electrode of the second transistor M2 is electrically connected to the first voltage signal terminal V1, and the second electrode of the second transistor M2 is electrically connected to the first pull-down node PD1.

The gate of the third transistor M3 is electrically connected to the pull-up node PU, the first electrode of the third transistor M3 is electrically connected to the second voltage signal terminal V2, and the second electrode of the third transistor M3 is electrically connected to the first pull-down node PD1.

The gate of the fourth transistor M4 is electrically connected to the input signal terminal Input, the first electrode of the fourth transistor M4 is electrically connected to the second voltage signal terminal V2, and the second electrode of the fourth transistor M4 is electrically connected to the first pull-down node PD1.

For example, as shown in FIG. 27, the second control circuit 10 includes the fourteenth transistor M14, the fifteenth transistor M15 and the sixteenth transistor M16.

The gate of the fourteenth transistor M14 is electrically connected to the fourth voltage signal terminal V4, the first electrode of the fourteenth transistor M14 is electrically connected to the fourth voltage signal terminal V4, and the second electrode of the fourteenth transistor M14 is electrically connected to the second pull-down node PD2.

The gate of the fifteenth transistor M15 is electrically connected to the pull-up node PU, the first electrode of the fifteenth transistor M15 is electrically connected to the second voltage signal terminal V2, and the second electrode of the fifteenth transistor M15 is electrically connected to the second pull-down node PD2.

The gate of the sixteenth transistor M16 is electrically connected to the input signal terminal Input, the first electrode of the sixteenth transistor M16 is electrically connected to the second voltage signal terminal V2, and the second electrode of the sixteenth transistor M16 is electrically connected to the second pull-down node PD2.

For example, as shown in FIG. 27, the output circuit 3 includes the fifth transistor M5 and the capacitor C.

The gate of the fifth transistor M5 is electrically connected to the pull-up node PU, the first electrode of the fifth transistor M5 is electrically connected to the clock signal terminal CLK, and the second electrode of the fifth transistor M5 is electrically connected to the first output signal terminal Out1.

The first terminal of the capacitor C is electrically connected to the pull-up node PU, and the second terminal of the capacitor C is electrically connected to the first output signal terminal Out1.

For example, as shown in FIG. 27, the first noise reduction circuit 4 includes the eighth transistor M8 and the seventeenth transistor M17.

The gate of the eighth transistor M8 is electrically connected to the first pull-down node PD1, the first electrode of the eighth transistor M8 is electrically connected to the third voltage signal terminal V3, and the second electrode of the eighth transistor M8 is electrically connected to the first output signal terminal Out1.

The gate of the seventeenth transistor M17 is electrically connected to the second pull-down node PD2, the first electrode of the seventeenth transistor M17 is electrically connected to the third voltage signal terminal V3, and the second electrode of the seventeenth transistor M17 is electrically connected to the first output signal terminal Out1.

For example, as shown in FIG. 27, the second noise reduction circuit 5 includes the ninth transistor M9 and the eighteenth transistor M18.

The gate of the ninth transistor M9 is electrically connected to the first pull-down node PD1, the first electrode of the ninth transistor M9 is electrically connected to the second voltage signal terminal V2, and the second electrode of the ninth transistor M9 is electrically connected to the pull-up node PU.

The gate of the eighteenth transistor M18 is electrically connected to the second pull-down node PD2, the first electrode of the eighteenth transistor M18 is electrically connected to the second voltage signal terminal V2, and the second electrode of the eighteenth transistor M18 is electrically connected to the pull-up node PU.

For example, as shown in FIG. 27, the first reset circuit 6 includes the tenth transistor M10.

The gate of the tenth transistor M10 is electrically connected to the first reset signal terminal Reset, the first electrode of the tenth transistor M10 is electrically connected to the second voltage signal terminal V2, and the second electrode of the tenth transistor M10 is electrically connected to the pull-up node PU.

For example, as shown in FIG. 27, the second reset circuit 7 includes the eleventh transistor M11.

The gate of the eleventh transistor M11 is electrically connected to the second reset signal terminal TRST, the first electrode of the eleventh transistor M11 is electrically connected to the second voltage signal terminal V2, and the second electrode of the eleventh transistor M11 is electrically connected to the pull-up node PU.

For example, as shown in FIG. 27, the cascade circuit 8 includes the twelfth transistor M12.

The gate of the twelfth transistor M12 is electrically connected to the pull-up node PU, the first electrode of the twelfth transistor M12 is electrically connected to the clock signal terminal CLK, and the second electrode of the twelfth transistor M12 is electrically connected to the second output signal terminal Out2.

For example, as shown in FIG. 27, the third noise reduction circuit 9 includes the thirteenth transistor M13 and the nineteenth transistor M19.

The gate of the thirteenth transistor M13 is electrically connected to the first pull-down node PD1, the first electrode of the thirteenth transistor M13 is electrically connected to the second voltage signal terminal V2, and the second electrode of the thirteenth transistor M13 is connected to the second output signal terminal Out2.

The gate of the nineteenth transistor M19 is electrically connected to the second pull-down node PD2, the first electrode of the nineteenth transistor M19 is electrically connected to the second voltage signal terminal V2, and the second electrode of the nineteenth transistor M19 is electrically connected to the second output signal terminal Out2.

For example, the above transistors are of a same type. For example, the transistors are all N-type transistors or P-type transistors.

Optionally, the transistors are all, for example, N-type transistors. In this case, each transistor is turned on under control of a high-level signal.

Selection criteria of the first transistor Ml, the third transistor M3 and the fifteenth transistor M15 are related to the load and the voltage of the display panel 2000.

As shown in FIG. 28, in an implementation, a shift register 100′ includes a first transistor M1′, a second transistor M2′, a third transistor M3′, a fifth transistor M5′, a sixth transistor M6′, a seventh transistor M7′, an eighth transistor M8′, a ninth transistor M9′, a tenth transistor M10′, an eleventh transistor M11′, a twelfth transistor M12′, a thirteenth transistor M13′, a fourteenth transistor M14′, a fifteenth transistor M15′, a seventeenth transistor M17′, an eighteenth transistor M18′, a nineteenth transistor M19′, a twentieth transistor M20′, a twenty-first transistor M21′ and a capacitor C′.

In the implementation, a first control circuit 2′ includes the sixth transistor M6′, and a second control circuit 10′ includes the twentieth transistor M20′. The first control circuit 2′ charges a first pull-down node PD1′ through the sixth transistor M6′ and the second transistor M2′. The second control circuit 10′ charges a second pull-down node PD2′ through the twentieth transistor M20′ and the fourteenth transistor M14′. In this way, speeds at which the first pull-down node PD1′ and the second pull-down node PD2′ are charged are slow, and charging capabilities of the first pull-down node PD1′ and the second pull-down node PD2′ are low. The low charging capabilities of the first pull-down node PD1′ and the second pull-down node PD2′ facilitate to improve a pre-charging capability of the pull-up node PU′, but will lead to display abnormalities of a display panel to which the shift register 100′ is applied at high temperature.

In some examples, in the shift register 100 shown in FIGS. 25 and 27, there are no the sixth transistor M6′, the seventh transistor M7′, the twentieth transistor M20′, and the twenty-first transistor M21′ in the implementation. In this way, the number of transistors through which the first voltage signal is transmitted to the first pull-down node PD1 is small, and the number of transistors through which the fourth voltage signal is transmitted to the second pull-down node PD2 is small; and the speeds at which the first pull-down node PD1 and the second pull-down node PD2 are charged are fast. Thus, the charging capabilities of the first pull-down node PD1 and the second pull-down node PD2 may be improved, and the display abnormalities of the display panel 2000 at high temperature may be reduced.

In some examples, as shown in FIGS. 21, 23, 25 and 27, the shift register 100 includes the fourth transistor M4 and the sixteenth transistor M16, and gates of the fourth transistor M4 and the sixteenth transistor M16 are electrically connected to the input signal terminal Input. In this way, when the input circuit 1 charges the pull-up node PU, the voltage of the first pull-down node PD1 or the voltage of the second pull-down node PD2 may be pulled down by using the input signal. Compared to that, in this implementation, only when a voltage of the pull-up node PU′ is pulled up to a high level, a voltage of the first pull-down node PD1′ may be pulled down through the seventh transistor M7′, the second transistor M2′ and the third transistor M3′, or a voltage of the second pull-down node PD2′ is pulled down through the twenty-first transistor M21′, the fourteenth transistor M14′ and the fifteenth transistor M15′, in the embodiments of the present disclosure, the voltages of the first pull-down node PD1 and the second pull-down node PD2 can be directly pulled down by using the input signal, so that the competition relationship between the pull-up node PU and the first pull-down node PD1, and a competition relationship between the pull-up node PU and the second pull-down node PD2 are eliminated. As a result, the pre-charging capability of the pull-up node PU may be improved, and the problem of poor startup performance of the shift register 100 at low temperature may be improved.

For example, the number of the transistors in the shift register 100 in the embodiments of the present disclosure is small, which facilitates to reduce the space occupied by the shift register 100, and to further reduce the size of the bezel area B of the display panel 2000, and to achieve the narrow bezel.

A comparison between a service life of a 19T1C shift register 100′ in the implementation shown in FIG. 28 at high temperature and a service life of a 17T1C shift register 100 shown in FIG. 27 provided in the embodiments of the present disclosure, is shown in Table 1 below.

TABLE 1

| Structure of shift register | | 19T1C | 17T1C |
|---|---|---|---|
| Service life | Maximum service | 2500 | Greater than 100000 |
| at high | life (h) | | (>100000) |
| temperature | Minimum service | 2100 | Greater than 100000 |
| (h) | life (h) | | (>100000) |

Data in the Table 1 is obtained through simulation calculation, and is only an example to show that the service life of the shift register 100 in the embodiments of the present disclosure is longer than the service life of the shift register 100′ in the implementation. To compare the service life of the shift register 100′ in the implementation to the service life of the shift register 100 in the embodiments of the present disclosure, for example, it is also possible to obtain test results by performing an aging test on a display apparatus using the shift register 100′ in the implementation and the display apparatus 2000 using the shift register 100 in the embodiments of the present disclosure that are placed in the same high temperature environment. However, a method of testing the service life of the shift register 100 is not limited in the present disclosure.

Some embodiments of the present disclosure provide the gate driving circuit 1000. As shown in FIGS. 29 to 31, the gate driving circuit 1000 includes the plurality of shift registers 100 connected in cascade.

As shown in FIGS. 29 to 31, A1, A2, . . . , An−1, and An respectively represent a first shift register 100, a second shift register 100, . . . , an (n−1)th shift register 100, and an nth shift register 100; Out1<1 >, Out1<2>, Out1<n−1>, and Out1<n> respectively represent a first output signal terminal Out1 of the first shift register 100, a first output signal Out1 of the second shift register 100, . . . , a first output signal terminal Out1 of the (n−1)th shift register 100, and a first output signal terminal Out1 of the nth shift register 100; Out2<1>, Out2<2>, . . . , Out2<n−1>, and Out2<n> respectively represent a second output signal terminal Out2 of the first shift register 100, a second output signal terminal Out2 of the second shift register 100, . . . , a second output signal terminal Out2 of the (n−1)th shift register 100, and a second output signal terminal Out2 of the nth shift register 100. Here, n is greater than or equal to 2 (n≥2), and n is an integer.

The plurality of shift registers 100 that are connected in cascade included in the gate driving circuit 1000 have various cascade relationships, which are related to the structure of the shift register 100.

In some examples, in a case where the shift register 100 does not include the cascade circuit 8 and the first reset circuit 6, the cascade relationship of the plurality of shift registers 100 that are connected in cascade included in the gate driving circuit 1000 may be as shown in FIG. 29.

The input signal terminal Input of the first shift register 100 may be electrically connected to the start signal terminal Stvp, and the start signal received at the start signal terminal Stvp is used as the input signal.

Except the last shift register 100, the first output signal terminal Out1 of each shift register 100 may be electrically connected to the input signal terminal Input of the next shift register 100, and the first output signal output by the first output signal terminal Out1 of each shift register 100 is used as the input signal of the next shift register 100.

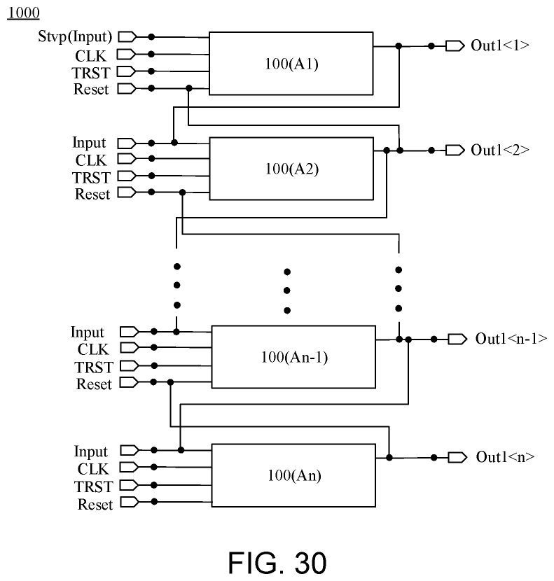

In some other examples, in a case where the shift register 100 does not include the cascade circuit 8 but includes the first reset circuit 6, the cascade relationship of the plurality of shift registers 100 that are connected in cascade included in the gate driving circuit 1000 may be as shown in FIG. 30.

The input signal terminal Input of the first shift register 100 may be electrically connected to the start signal terminal Stvp, and the start signal received at the start signal terminal Stvp is used as the input signal.

Except the last shift register 100, the first output signal terminal Out1 of each shift register 100 may be electrically connected to the input signal terminal Input of the next shift register 100, and the first output signal output by the first output signal terminal Out1 of each shift register 100 is used as the input signal of the next shift register 100.

Except the first shift register 100, the first output signal terminal Out1 of each shift register 100 is electrically connected to the first reset signal terminal Reset of the previous shift register 100, and the first output signal output by the first output signal terminal Out1 of each shift register 100 is used as a first reset signal of the previous shift register 100.

That is, except the first shift register 100 and the last shift register 100, the first output signal terminal Out1 of each shift register 100 is electrically connected to the first reset signal terminal Reset of the previous shift register 100 and the input signal terminal Input of the next shift register 100.

In yet some other examples, in a case where the shift register 100 includes the cascade circuit 8 and the first reset circuit 6, the cascade relationship of the plurality of shift registers 100 that are connected in cascade included in the gate driving circuit 1000 may be as shown in FIG. 31.

The input signal terminal Input of the first shift register 100 may be electrically connected to the start signal terminal Stvp, and the start signal received at the start signal terminal Stvp is used as the input signal.

Except the last shift register 100, a second output signal terminal Out2 of each shift register 100 is electrically connected to the input signal terminal Input of the next shift register 100, and the second output signal output by the second output signal terminal Out2 of each shift register 100 is used as the input signal of the next shift register 100.

Except the first shift register 100, the second output signal terminal Out2 of each shift register 100 is electrically connected to the first reset signal terminal Reset of the previous shift register 100, and the second output signal output by the second output signal terminal Out2 of each shift register 100 is used as the first reset signal of the previous shift register 100.

That is, except the first shift register 100 and the last shift 100, the second output signal terminal Out2 of each shift register 100 is electrically connected to the first reset signal terminal Reset of the previous shift register 100 and the input signal terminal Input of the next shift register 100.

It will be noted that in FIGS. 29 to 31, only shift registers 100 that provide scanning signals to pixel driving circuits 200 are shown. That is, the first shift register 100 to the nth shift register 100 may each provide a scanning signal to pixel driving circuits 200. However, the structure of the gate driving circuit 1000 in the present disclosure is not limited thereto.

For example, the gate driving circuit 1000 may further include some pre-units and post-units. The pre-units each include at least one shift register 100 used to provide the start signal for the first shift register. The post-unit includes at least one shift register 100 used to provide the first reset signal for the nth shift register 100. In a case where the pre-unit and the post-unit each include shift registers 100, the cascade relationship of the plurality of shift registers 100 included in the gate driving circuit 1000 are still as shown in FIGS. 29 to 31, but first output signal terminals Out1 of the shift registers 100 in the pre-unit and first output signal terminals Out1 of the shift registers 100 in the post-unit are not electrically connected to pixel driving circuits 200.

FIG. 32 is a diagram showing an operation timing of the shift register 100. In FIG. 32, Ot1<1> and Ot1<2> respectively represent a first output signal output by the first output signal terminal Out1 of the first shift register 100 and a first output signal output by the first output signal terminal Out1 of the second shift register 100. Ot2<1> and Ot2<2> respectively represent a second output signal output by the second output signal terminal Out2 of the first shift register 100 and a second output signal output by the second output signal terminal Out2 of the second shift register 100.

A control method for the shift register 100 provided in the embodiments of the present disclosure will be exemplarily described below in combination with FIG. 32.

In a display period in a frame, an operation process of the first shift register 100 is described as follows.

In a first period t1 (i.e., an input period), the start signal Stvp′ is at a high level. That is, the input signal Input′ provided to the input signal terminal Input of the input circuit 1 is at a high level. The input circuit 1 may be turned on under the control of the input signal Input′, and transmit the input signal Input′ to the pull-up node PU to charge the pull-up node PU, so as to pull up the voltage PU′ of the pull-up node PU (e.g., pulling it up to the level a).

The first control circuit 2 is turned on under the control of the input signal Input′, and transmits the second voltage signal V2′ to the first pull-down node PD1, so as to pull down the voltage of the first pull-down node PD1. After the voltage PU′ of the pull-up node PU is pulled up, the third transistor M3 in the first control circuit 2 is turned on under the control of the voltage PU′ of the pull-up node PU, and transmits the second voltage signal V2′ to the first pull-down node PD1, so as to pull down the voltage of the first pull-down node PD1.

The output circuit 3 is turned on under the control of the voltage PU′ of the pull-up node PU, and transmits the clock signal CLK′ received at the clock signal terminal CLK to the first output signal terminal Out1. Since the clock signal CLK′ is at a low level, the first output signal output by the first output signal terminal Out1 is at a low level.

In the first period t1, the input signal Input′ is at the high level, and the first transistor M1 in the input circuit 1 and the fourth transistor M4 in the first control circuit 2 may be turned on under the control of the input signal Input′. The first voltage signal V1′ is at a high level, and the second transistor M2 in the first control circuit 2 may be turned on under the control of the first voltage signal V1′.

The first transistor M1 charges the pull-up node PU and pulls up the voltage PU′ of the pull-up node PU to the level a. The second transistor M2 charges the first pull-down node PD1, and the fourth transistor M4 transmits the second voltage signal V2′ received at the second voltage signal terminal V2 to the first pull-down node PD1, so that the voltage of the first pull-down node PD1 is pulled down, and the voltage of the first pull-down node PD1 is at a low level.

In a case where the voltage PU′ of the pull-up node PU is pulled up to the level a, the third transistor M3 in the first control circuit 2 and the fifth transistor M5 in the output circuit 3 may be turned on under the control of the voltage PU′ of the pull-up node PU. The third transistor M3 transmits the second voltage signal V2′ received at the second voltage signal terminal V2 to the first pull-down node PD1, so as to pull down the voltage of the first pull-down node PD1, and the fifth transistor M5 transmits the low-level clock signal CLK′ received at the clock signal terminal CLK to the first output signal terminal Out1.

In this period, the input circuit 1 also charges the capacitor C.

In a second period t2, the first control circuit 2 pulls down the voltage PD1′ of the first pull-down node PD1 under the control of the voltage PU′ of the pull-up node PU; and the output circuit 3 transmits the clock signal CLK′ received at the clock signal terminal CLK to the first output signal terminal Out1 under the control of the voltage PU′ of the pull-up node PU.

In the second period t2, the input signal Input′ is at a low level, the first transistor M1 and the fourth transistor M4 are turned off, and the pull-up node PU is in a floating state. At this moment (a start moment of the second period t2), the voltage PU′ of the pull-up node PU is the level a, and the fifth transistor M5 is maintained in a turn-on state.

The level of the clock signal CLK′ changes from the low level to a high level. Due to a bootstrap action of the capacitor C, the voltage PU′ of the pull-up node PU is pulled up from the level a to the level b. The fifth transistor M5 transmits the high-level clock signal CLK′ to the first output signal terminal Out1, and the first output signal terminal Out1 outputs a high-level first output signal.

The voltage PU′ of the pull-up node PU is at a high level. The third transistor M3 is maintained in a turn-on state, and continues to pull down the voltage PD1′ of the first pull-down node PD1.

In a third period t3, the voltage PU′ of the pull-up node PU is pulled down. The first control circuit 2 transmits the high-level first voltage signal V1′ to the first pull-down node PD1, so as to pull up the voltage of the first pull-down node PD1. The second noise reduction circuit 6 is turned on under the control of the voltage of the first pull-down node PD1, and transmits the second voltage signal V2′ received at the second voltage signal terminal V2 to the pull-up node PU, so as to reduce the noise of the pull-up node PU. The first noise reduction circuit 4 is turned on under the control of the voltage of the first pull-down node PD1, and transmits the third voltage signal V3′ received at the third voltage signal terminal V3 to the first output signal terminal Out1, so as to reduce the noise of the first output signal terminal Out1.

In the third period t3, the first reset signal is at a high level, and the tenth transistor M10 in the first reset circuit 6 is turned on, and transmits the second voltage signal V2′ received at the second voltage signal terminal V2 to the pull-up node PU to reset the pull-up node PU, so as to pull down the voltage PU′ of the pull-up node PU. At this time, the third transistor M3 and the fifth transistor M5 may be turned off under the control of the voltage PU′ of the pull-up node PU.

The second transistor M2 in the first control circuit 2 is maintained in a turn-on state, and charges the first pull-down node PD1, so that the voltage of the first pull-down node PD1 changes to be at a high level. The ninth transistor M9 and the eighth transistor M8 may be turned on under the control of the voltage of the first pull-down node PD1. The ninth transistor M9 may transmit the second voltage signal to the pull-up node PU to reduce the noise of the pull-up node PU, which prevents the fifth transistor M5 from being turned on by mistake due to that an external abnormal voltage affects the voltage of the pull-up node PU. The eighth transistor M8 transmits the third voltage signal to the first output signal terminal Out1 to reduce the noise of the first output signal terminal Out1.

In a fourth period t4, the voltage of the pull-up node PU is maintained to be at a low level, and this period is also referred to as a holding period.

In a fifth period t5, the second reset signal TRST′ transmitted by the second reset signal terminal TRST is at a high level. The eleventh transistor M11 in the second reset circuit 7 is turned on under the control of the second reset signal, and transmits the second voltage signal received at the second voltage signal terminal V2 to the pull-up node PU to reset the pull-up node PU, so as to avoid an abnormal voltage of the pull-up node PU caused by the external abnormal voltage, which causes the fifth transistor M5 to be turned on, and in turn causes the first output signal output by the first output signal terminal Out1 to be abnormal.

It will be noted that, in the accompanying drawings of the description of the present disclosure, nodes where wires cross and are connected are marked with solid dots, and nodes where wires cross but are not marked with dots indicate that the wires are not connected.

The foregoing descriptions are merely specific implementations of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. A shift register, comprising:
an input circuit electrically connected to an input signal terminal and a pull-up node, the input circuit being configured to, under control of an input signal transmitted by the input signal terminal, transmit the input signal to the pull-up node;
a first control circuit electrically connected to a first voltage signal terminal, the pull-up node, a first pull-down node and a second voltage signal terminal, the first control circuit being configured to: under control of a first voltage signal transmitted by the first voltage signal terminal, transmit the first voltage signal to the first pull-down node; and under control of a voltage of the pull-up node, transmit a second voltage signal received at the second voltage signal terminal to the first pull-down node; and
an output circuit electrically connected to the pull-up node, a clock signal terminal and a first output signal terminal, the output circuit being configured to transmit a clock signal received at the clock signal terminal to the first output signal terminal under the control of the voltage of the pull-up node; wherein
the first control circuit is further electrically connected to the input signal terminal; the first control circuit is further configured to, in a period when the input circuit transmits the input signal to the pull-up node, receive the input signal, and transmit the second voltage signal to the first pull-down node under the control of the input signal.

2. The shift register according to claim 1, wherein the first control circuit includes:
a second transistor, wherein a gate of the second transistor is electrically connected to the first voltage signal terminal, a first electrode of the second transistor is electrically connected to the first voltage signal terminal, and a second electrode of the second transistor is electrically connected to the first pull-down node;
a third transistor, wherein a gate of the third transistor is electrically connected to the pull-up node, a first electrode of the third transistor is electrically connected to the second voltage signal terminal, and a second electrode of the third transistor is electrically connected to the first pull-down node; and
a fourth transistor, wherein a gate of the fourth transistor is electrically connected to the input signal terminal, a first electrode of the fourth transistor is electrically connected to the second voltage signal terminal, and a second electrode of the fourth transistor is electrically connected to the first pull-down node.

3. The shift register according to claim 2, wherein the first control circuit further includes:
a sixth transistor, wherein a gate of the sixth transistor is electrically connected to the first voltage signal terminal, a first electrode of the sixth transistor is electrically connected to the first voltage signal terminal, and a second electrode of the sixth transistor is electrically connected to the gate of the second transistor.

4. The shift register according to claim 3, wherein the first control circuit further includes:
a seventh transistor, wherein a gate of the seventh transistor is electrically connected to the pull-up node, a first electrode of the seventh transistor is electrically connected to the second voltage signal terminal, and a second electrode of the seventh transistor is electrically connected to the second electrode of the sixth transistor.

5. The shift register according to claim 1, wherein
the input circuit includes:
a first transistor, wherein a gate of the first transistor is electrically connected to the input signal terminal, a first electrode of the first transistor is electrically connected to the input signal terminal, and a second electrode of the first transistor is electrically connected to the pull-up node; and
the output circuit includes:
a fifth transistor, wherein a gate of the fifth transistor is electrically connected to the pull-up node, a first electrode of the fifth transistor is electrically connected to the clock signal terminal, and a second electrode of the fifth transistor is electrically connected to the first output signal terminal; and
a capacitor, wherein a first terminal of the capacitor is electrically connected to the pull-up node, and a second terminal of the capacitor is electrically connected to the first output signal terminal.

6. The shift register according to claim 1, further comprising:
a first noise reduction circuit4s electrically connected to the first pull-down node, the first output signal terminal and a third voltage signal terminal, wherein the first noise reduction circuit is configured to transmit a third voltage signal received at the third voltage signal terminal to the first output signal terminal under control of a voltage of the first pull-down node, so as to reduce noise of the first output signal terminal; and/or
a second noise reduction circuit electrically connected to the pull-up node, the second voltage signal terminal and the first pull-down node, wherein the second noise reduction circuit is configured to transmit the second voltage signal received at the second voltage signal terminal to the pull-up node under the control of the voltage of the first pull-down node, so as to reduce noise of the pull-up node.

7. The shift register according to claim 6, wherein
the first noise reduction circuit includes:
an eighth transistor, wherein a gate of the eighth transistor is electrically connected to the first pull-down node, a first electrode of the eighth transistor is electrically connected to the third voltage signal terminal, and a second electrode of the eighth transistor is electrically connected to the first output signal terminal; and
the second noise reduction circuit includes:
a ninth transistor, wherein a gate of the ninth transistor is electrically connected to the first pull-down node, a first electrode of the ninth transistor is electrically connected to the second voltage signal terminal, and a second electrode of the ninth transistor is electrically connected to the pull-up node.

8. (canceled)

9. The shift register according to claim 1, further comprising:
a first reset circuit electrically connected to the pull-up node, a first reset signal terminal and the second voltage signal terminal, wherein the first reset circuit is configured to transmit the second voltage signal received at the second voltage signal terminal to the pull-up node under control of a first reset signal transmitted by the first reset signal terminal, so as to reset the pull-up node; and/or
a second reset circuit electrically connected to a second reset signal terminal, the pull-up node and the second voltage signal terminal, wherein the second reset circuit is configured to transmit the second voltage signal received at the second voltage signal terminal to the pull-up node under control of a second reset signal transmitted by the second reset signal terminal, so as to reset the pull-up node.

10. The shift register according to claim 9, wherein
the first reset circuit includes:
a tenth transistor, wherein a gate of the tenth transistor is electrically connected to the first reset signal terminal, a first electrode of the tenth transistor is electrically connected to the second voltage signal terminal, and a second electrode of the tenth transistor is electrically connected to the pull-up node; and
the second reset circuit includes:
an eleventh transistor, wherein a gate of the eleventh transistor is electrically connected to the second reset signal terminal, a first electrode of the eleventh transistor is electrically connected to the second voltage signal terminal, and a second electrode of the eleventh transistor is electrically connected to the pull-up node.

11. The shift register according to claim 1, further comprising:
a cascade circuit electrically connected to the pull-up node, the clock signal terminal and a second output signal terminal, wherein the cascade circuit is configured to transmit the clock signal received at the clock signal terminal to the second output signal terminal under the control of the voltage of the pull-up node; or
a cascade circuit electrically connected to the pull-up node, the clock signal terminal and a second output signal terminal, wherein the cascade circuit is configured to transmit the clock signal received at the clock signal terminal to the second output signal terminal under the control of the voltage of the pull-up node; and
a third noise reduction circuit electrically connected to the first pull-down node, the second output signal terminal and the second voltage signal terminal, wherein the third noise reduction circuit is configured to transmit the second voltage signal received at the second voltage signal terminal to the second output signal terminal under control of a voltage of the first pull-down node, so as to reduce noise of the second output signal terminal.

12. The shift register according to claim 11, wherein the cascade circuit includes:
a twelfth transistor, wherein a gate of the twelfth transistor is electrically connected to the pull-up node, a first electrode of the twelfth transistor is electrically connected to the clock signal terminal, and a second electrode of the twelfth transistor is electrically connected to the second output signal terminal; and/or
the third noise reduction circuit includes:
a thirteenth transistor, wherein a gate of the thirteenth transistor is electrically connected to the first pull-down node, a first electrode of the thirteenth transistor is electrically connected to the second voltage signal terminal, and a second electrode of the thirteenth transistor is electrically connected to the second output signal terminal.

13-14. (canceled)

15. The shift register according to claim 1, further comprising:
a second control circuit electrically connected to a fourth voltage signal terminal, the pull-up node, a second pull-down node and the second voltage signal terminal, wherein the second control circuit is configured to: under control of a fourth voltage signal transmitted by the fourth voltage signal terminal, transmit the fourth voltage signal to the second pull-down node; and under the control of the voltage of the pull-up node, transmit the second voltage signal received at the second voltage signal terminal to the second pull-down node; and the second control circuit is further electrically connected to the input signal terminal; the second control circuit is further configured to, in the period when the input circuit transmits the input signal to the pull-up node, receive the input signal, and transmit the second voltage signal to the second pull-down node under the control of the input signal;
a first noise reduction circuit electrically connected to the first pull-down node, the first output signal terminal and a third voltage signal terminal, wherein the first noise reduction circuit is configured to transmit a third voltage signal received at the third voltage signal terminal to the first output signal terminal under control of a voltage of the first pull-down node, so as to reduce noise of the first output signal terminal; and the first noise reduction circuit is further electrically connected to the second pull-down node; the first noise reduction circuit is further configured to transmit the third voltage signal received at the third voltage signal terminal to the first output signal terminal under control of a voltage of the second pull-down node, so as to reduce noise of the first output signal terminal;
a second noise reduction circuit electrically connected to the pull-up node, the second voltage signal terminal and the first pull-down node, wherein the second noise reduction circuit is configured to transmit the second voltage signal received at the second voltage signal terminal to the pull-up node under the control of the voltage of the first pull-down node, so as to reduce noise of the pull-up node; and the second noise reduction circuit is further electrically connected to the second pull-down node; the second noise reduction circuit is further configured to transmit the second voltage signal received at the second voltage signal terminal to the pull-up node under the control of the voltage of the second pull-down node, so as to reduce noise of the pull-up node;
a cascade circuit electrically connected to the pull-up node, the clock signal terminal and a second output signal terminal, wherein the cascade circuit is configured to transmit the clock signal received at the clock signal terminal to the second output signal terminal under the control of the voltage of the pull-up node; and
a third noise reduction circuit electrically connected to the first pull-down node, the second output signal terminal and the second voltage signal terminal, wherein the third noise reduction circuit is configured to transmit the second voltage signal received at the second voltage signal terminal to the second output signal terminal under the control of the voltage of the first pull-down node, so as to reduce noise of the second output signal terminal; the third noise reduction circuit is further electrically connected to the second pull-down node; and the third noise reduction circuit is further configured to transmit the second voltage signal received at the second voltage signal terminal to the second output signal terminal under the control of the voltage of the second pull-down node, so as to reduce noise of the second output signal terminal.

16. The shift register according to claim 15, wherein the second control circuit includes:
a fourteenth transistor, wherein a gate of the fourteenth transistor is electrically connected to the fourth voltage signal terminal, a first electrode of the fourteenth transistor is electrically connected to the fourth voltage signal terminal, and a second electrode of the fourteenth transistor is electrically connected to the second pull-down node;
a fifteenth transistor, wherein a gate of the fifteenth transistor is electrically connected to the pull-up node, a first electrode of the fifteenth transistor is electrically connected to the second voltage signal terminal, and a second electrode of the fifteenth transistor is electrically connected to the second pull-down node; and
a sixteenth transistor, wherein a gate of the sixteenth transistor is electrically connected to the input signal terminal, a first electrode of the sixteenth transistor is electrically connected to the second voltage signal terminal, and a second electrode of the sixteenth transistor is electrically connected to the second pull-down node;
the first noise reduction circuit includes:
an eighth transistor, wherein a gate of the eighth transistor is electrically connected to the first pull-down node, a first electrode of the eighth transistor is electrically connected to the third voltage signal terminal, and a second electrode of the eighth transistor is electrically connected to the first output signal terminal; and
a seventeenth transistor, wherein a gate of the seventeenth transistor is electrically connected to the second pull-down node, a first electrode of the seventeenth transistor is electrically connected to the third voltage signal terminal, and a second electrode of the seventeenth transistor is electrically connected to the first output signal terminal;
the second noise reduction circuit includes:
a ninth transistor, wherein a gate of the ninth transistor is electrically connected to the first pull-down node, a first electrode of the ninth transistor is electrically connected to the second voltage signal terminal, and a second electrode of the ninth transistor is electrically connected to the pull-up node; and
an eighteenth transistor, wherein a gate of the eighteenth transistor is electrically connected to the second pull-down node, a first electrode of the eighteenth transistor is electrically connected to the second voltage signal terminal, and a second electrode of the eighteenth transistor is electrically connected to the pull-up node; and
the third noise reduction circuit includes:
a thirteenth transistor, wherein a gate of the thirteenth transistor is electrically connected to the first pull-down node, a first electrode of the thirteenth transistor is electrically connected to the second voltage signal terminal, and a second electrode of the thirteenth transistor is electrically connected to the second output signal terminal; and
a nineteenth transistor, wherein a gate of the nineteenth transistor is electrically connected to the second pull-down node, a first electrode of the nineteenth transistor is electrically connected to the second voltage signal terminal, and a second electrode of the nineteenth transistor is electrically connected to the second output signal terminal.

17. The shift register according to claim 16, wherein the second control circuit further includes a twentieth transistor, wherein
a gate of the twentieth transistor is electrically connected to the fourth voltage signal terminal, a first electrode of the twentieth transistor is electrically connected to the fourth voltage signal terminal, and a second electrode of the twentieth transistor is electrically connected to the gate of the fourteenth transistor.

18. The shift register according to claim 17, wherein the second control circuit further includes a twenty-first transistor, wherein
a gate of the twenty-first transistor is electrically connected to the pull-up node, a first electrode of the twenty-first transistor is electrically connected to the second voltage signal terminal, and a second electrode of the twenty-first transistor is electrically connected to the second electrode of the twentieth transistor.

19. A shift register, comprising:
an input circuit electrically connected to an input signal terminal and a pull-up node, the input circuit being configured to, under control of an input signal transmitted by the input signal terminal, transmit the input signal to the pull-up node;
a first control circuit electrically connected to a first voltage signal terminal, the pull-up node, a first pull-down node and a second voltage signal terminal, the first control circuit being configured to: under control of a first voltage signal transmitted by the first voltage signal terminal, transmit the first voltage signal to the first pull-down node; and under control of a voltage of the pull-up node, transmit a second voltage signal received at the second voltage signal terminal to the first pull-down node;
a second control circuit electrically connected to a fourth voltage signal terminal, the pull-up node, a second pull-down node and the second voltage signal terminal, the second control circuit being configured to: under control of a fourth voltage signal transmitted by the fourth voltage signal terminal, transmit the fourth voltage signal to the second pull-down node; and under the control of the voltage of the pull-up node, transmit the second voltage signal received at the second voltage signal terminal to the second pull-down node;
an output circuit electrically connected to the pull-up node, a clock signal terminal and a first output signal terminal, the output circuit being configured to transmit a clock signal received at the clock signal terminal to the first output signal terminal under the control of the voltage of the pull-up node;
a first noise reduction circuit electrically connected to the first pull-down node, the second pull-down node, the first output signal terminal and a third voltage signal terminal, the first noise reduction circuit being configured to: transmit a third voltage signal received at the third voltage signal terminal to the first output signal terminal under control of a voltage of the first pull-down node, so as to reduce noise of the first output signal terminal; and transmit the third voltage signal received at the third voltage signal terminal to the first output signal terminal under control of a voltage of the second pull-down node, so as to reduce the noise of the first output signal terminal;
a second noise reduction circuit electrically connected to the pull-up node, the second pull-down node, the second voltage signal terminal and the first pull-down node, the second noise reduction circuit being configured to: transmit the second voltage signal received at the second voltage signal terminal to the pull-up node under the control of the voltage of the first pull-down node, so as to reduce noise of the pull-up node; and transmit the second voltage signal received at the second voltage signal terminal to the pull-up node under the control of the voltage of the second pull-down node, so as to reduce the noise of the pull-up node;
a first reset circuit electrically connected to the pull-up node, a first reset signal terminal and the second voltage signal terminal, the first reset circuit being configured to transmit the second voltage signal received at the second voltage signal terminal to the pull-up node under control of a first reset signal transmitted by the first reset signal terminal, so as to reset the pull-up node;
a second reset circuit electrically connected to a second reset signal terminal, the pull-up node and the second voltage signal terminal, the second reset circuit being configured to transmit the second voltage signal received at the second voltage signal terminal to the pull-up node under control of a second reset signal transmitted by the second reset signal terminal, so as to reset the pull-up node;
a cascade circuit electrically connected to the pull-up node, the clock signal terminal and a second output signal terminal, the cascade circuit being configured to transmit the clock signal received at the clock signal terminal to the second output signal terminal under the control of the voltage of the pull-up node; and
a third noise reduction circuit electrically connected to the first pull-down node, the second pull-down node, the second output signal terminal and the second voltage signal terminal, the third noise reduction circuit being configured to: transmit the second voltage signal received at the second voltage signal terminal to the second output signal terminal under the control of the voltage of the first pull-down node, so as to reduce noise of the second output signal terminal; and transmit the second voltage signal received at the second voltage signal terminal to the second output signal terminal under the control of the voltage of the second pull-down node, so as to reduce the noise of the second output signal terminal; wherein
the first control circuit is further electrically connected to the input signal terminal; the first control circuit is further configured to, in a period when the input circuit transmits the input signal to the pull-up node, receive the input signal, and transmit the second voltage signal to the first pull-down node under the control of the input signal; and
the second control circuit is further electrically connected to the input signal terminal; the second control circuit is further configured to, in the period when the input circuit transmits the input signal to the pull-up node, receive the input signal, and transmit the second voltage signal to the second pull-down node under the control of the input signal.

20. The shift register according to claim 19, wherein
the input circuit includes:
a first transistor, wherein a gate of the first transistor is electrically connected to the input signal terminal, a first electrode of the first transistor is electrically connected to the input signal terminal, and a second electrode of the first transistor is electrically connected to the pull-up node;
the first control circuit includes:
a second transistor, wherein a gate of the second transistor is electrically connected to the first voltage signal terminal, a first electrode of the second transistor is electrically connected to the first voltage signal terminal, and a second electrode of the second transistor is electrically connected to the first pull-down node;
a third transistor, wherein a gate of the third transistor is electrically connected to the pull-up node, a first electrode of the third transistor is electrically connected to the second voltage signal terminal, and a second electrode of the third transistor is electrically connected to the first pull-down node; and
a fourth transistor, wherein a gate of the fourth transistor is electrically connected to the input signal terminal, a first electrode of the fourth transistor is electrically connected to the second voltage signal terminal, and a second electrode of the fourth transistor is electrically connected to the first pull-down node;
the second control circuit includes:
a fourteenth transistor, wherein a gate of the fourteenth transistor is electrically connected to the fourth voltage signal terminal, a first electrode of the fourteenth transistor is electrically connected to the fourth voltage signal terminal, and a second electrode of the fourteenth transistor is electrically connected to the second pull-down node;
a fifteenth transistor, wherein a gate of the fifteenth transistor is electrically connected to the pull-up node, a first electrode of the fifteenth transistor is electrically connected to the second voltage signal terminal, and a second electrode of the fifteenth transistor is electrically connected to the second pull-down node; and
a sixteenth transistor, wherein a gate of the sixteenth transistor is electrically connected to the input signal terminal, a first electrode of the sixteenth transistor is electrically connected to the second voltage signal terminal, and a second electrode of the sixteenth transistor is electrically connected to the second pull-down node;
the output circuit includes:
a fifth transistor, wherein a gate of the fifth transistor is electrically connected to the pull-up node, a first electrode of the fifth transistor is electrically connected to the clock signal terminal, and a second electrode of the fifth transistor is electrically connected to the first output signal terminal; and
a capacitor, wherein a first terminal of the capacitor is electrically connected to the pull-up node, and a second terminal of the capacitor is electrically connected to the first output signal terminal;
the first noise reduction circuit includes:
an eighth transistor, wherein a gate of the eighth transistor is electrically connected to the first pull-down node, a first electrode of the eighth transistor is electrically connected to the third voltage signal terminal, and a second electrode of the eighth transistor is electrically connected to the first output signal terminal; and
a seventeenth transistor, wherein a gate of the seventeenth transistor is electrically connected to the second pull-down node, a first electrode of the seventeenth transistor is electrically connected to the third voltage signal terminal, and a second electrode of the seventeenth transistor is electrically connected to the first output signal terminal;
the second noise reduction circuit includes:
a ninth transistor, wherein a gate of the ninth transistor is electrically connected to the first pull-down node, a first electrode of the ninth transistor is electrically connected to the second voltage signal terminal, and a second electrode of the ninth transistor is electrically connected to the pull-up node; and
an eighteenth transistor, wherein a gate of the eighteenth transistor is electrically connected to the second pull-down node, a first electrode of the eighteenth transistor is electrically connected to the second voltage signal terminal, and a second electrode of the eighteenth transistor is electrically connected to the pull-up node;
the first reset circuit includes:
a tenth transistor, wherein a gate of the tenth transistor is electrically connected to the first reset signal terminal, a first electrode of the tenth transistor is electrically connected to the second voltage signal terminal, and a second electrode of the tenth transistor is electrically connected to the pull-up node;
the second reset circuit includes:
an eleventh transistor, wherein a gate of the eleventh transistor is electrically connected to the second reset signal terminal, a first electrode of the eleventh transistor is electrically connected to the second voltage signal terminal, and a second electrode of the eleventh transistor is electrically connected to the pull-up node;
the cascade circuit includes:
a twelfth transistor, wherein a gate of the twelfth transistor is electrically connected to the pull-up node, a first electrode of the twelfth transistor is electrically connected to the clock signal terminal, and a second electrode of the twelfth transistor is electrically connected to the second output signal terminal; and
the third noise reduction circuit includes:
a thirteenth transistor, wherein a gate of the thirteenth transistor is electrically connected to the first pull-down node, a first electrode of the thirteenth transistor is electrically connected to the second voltage signal terminal, and a second electrode of the thirteenth transistor is connected to the second output signal terminal; and
a nineteenth transistor, wherein a gate of the nineteenth transistor is electrically connected to the second pull-down node, a first electrode of the nineteenth transistor is electrically connected to the second voltage signal terminal, and a second electrode of the nineteenth transistor is electrically connected to the second output signal terminal.

21. (canceled)

22. A gate driving circuit, comprising a plurality of shift registers connected in cascade according to claim 1, wherein
in the plurality of shift registers connected in cascade in the gate driving circuit, an input signal terminal of a first shift register is electrically connected to a start signal terminal; and except the first shift register, an input signal terminal of each shift register is electrically connected to a first output signal terminal of a previous shift register; or
the shift register further includes a cascade circuit electrically connected to the pull-up node, the clock signal terminal and a second output signal terminal, and configured to transmit the clock signal received at the clock signal terminal to the second output signal terminal under the control of the voltage of the pull-up node; in the plurality of shift registers connected in cascade in the gate driving circuit, an input signal terminal of a first shift register is electrically connected to a start signal terminal; and except the first shift register, an input signal terminal of each shift register is electrically connected to a second output signal terminal of a previous shift register.

23. (canceled)

24. A display panel, comprising the gate driving circuit according to claim 22.

25. A control method for the shift register according to claim 1, the control method comprising:
in an input period, in response to the input signal received at the input signal terminal, the input circuit being turned on, and transmitting the input signal to the pull-up node;
in response to the input signal received at the input signal terminal, the first control circuit being turned on, and transmitting the second voltage signal received at the second voltage signal terminal to the first pull-down node;
transmitting, by the first control circuit, the second voltage signal to the first pull-down node under the control of the voltage of the pull-up node; and
under the control of the voltage of the pull-up node, the output circuit being turned on, and transmitting the clock signal received at the clock signal terminal to the first output signal terminal.
